(19) United States
(12) Patent Application Publication
(10) Pub. No.: US 2022/0384498 A1
(43) Pub. Date: Dec. 1, 2022

(54) SOLID-STATE IMAGING DEVICE AND ELECTRONIC EQUIPMENT

(71) Applicant: SONY SEMICONDUCTOR SOLUTIONS CORPORATION, KANAGAWA (JP)

(72) Inventors: YASUFUMI KOBAYASHI, TOKYO (JP); TAKURO MURASE, KANAGAWA (JP)

(21) Appl. No.: 17/755,897

(22) PCT Filed: Nov. 2, 2020
(86) PCT No.: PCT/JP2020/041009

§ 371 Date: May 11, 2022

(30) Foreign Application Priority Data
Nov. 20, 2019 (JP) 2019-209510

(51) Int. Cl. H01L 27/146; H04N 5/369

(52) U.S. Cl. CPC H01L 27/14605; H04N 5/3696; H01L 27/14627

(57) ABSTRACT

A solid-state imaging device capable of improving image quality and functionality is provided.

Provided is a solid-state imaging device including a pixel region in which a plurality of pixels are two-dimensionally disposed, in which each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and the number of irregularities of a concavo-convex portion included in a pixel disposed in a central portion of the pixel region and the number of irregularities of a concavo-convex portion included in a pixel disposed in a peripheral portion of the pixel region are different from each other.

### TECHNICAL FIELD

The present technology relates to a solid-state imaging device and electronic equipment.

### BACKGROUND ART

In recent years, digital cameras have become increasingly popular, and the demand for solid-state imaging devices (image sensors), which are the core components of digital cameras, is increasing. Along with this, technological developments for achieving high image quality and high functionality in solid-state imaging devices are being actively performed. For example, technology related to photoelectric conversion devices in which a concavo-convex shape is formed in the thickness direction of a substrate to improve sensitivity characteristics has been proposed (see PTL 1).

### CITATION LIST

### Patent Literature

[PTL 1]

JP 2005-72097 A

### SUMMARY

### Technical Problem

However, in the technology proposed in PTL 1, there is a concern that it is not possible to achieve higher image quality and higher functionality.

Consequently, the present technology is contrived in view of such circumstances, and an object thereof is to provide a solid-state imaging device that can further improve image quality and functionality, and electronic equipment on which the solid-state imaging device is mounted.

### Solution to Problem

As a result of ardent research to solve the above-mentioned object, the inventor has succeeded in further improving image quality and functionality of a solid-state imaging device, and has completed the present technology.

That is, in the present technology, as a first aspect, provided is a solid-state imaging device including a pixel region in which a plurality of pixels are two-dimensionally disposed, in which each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and the number of irregularities of a concavo-convex portion included in a pixel disposed in a central portion of the pixel region and the number of irregularities of a concavo-convex portion included in a pixel disposed in a peripheral portion of the pixel region are different from each other.

In the solid-state imaging device according to the first aspect of the present technology, the number of irregularities of the concavo-convex portion included in the pixel disposed in the central portion of the pixel region may be smaller than the number of irregularities of the concavo-convex portion included in the pixel disposed in the peripheral portion of the pixel region.

In the solid-state imaging device according to the first aspect of the present technology, the number of irregularities of the concavo-convex portion included in each pixel constituting the plurality of pixels may change from the pixel disposed in the central portion of the pixel region to the pixel disposed in the peripheral portion of the pixel region.

In the solid-state imaging device according to the first aspect of the present technology, the number of irregularities of the concavo-convex portion included in each pixel constituting the plurality of pixels may gradually increase from the pixel disposed in the central portion of the pixel region to the pixel disposed in the peripheral portion of the pixel region.

In the solid-state imaging device according to the first aspect of the present technology, a pitch of a convex portion constituting the concavo-convex portion included in the pixel disposed in the central portion of the pixel region and a pitch of a convex portion constituting the concavo-convex portion included in the pixel disposed in the peripheral portion of the pixel region may be different from each other.

In the solid-state imaging device according to the first aspect of the present technology, a pitch of a convex portion constituting the concavo-convex portion included in the pixel disposed in the central portion of the pixel region may be larger than a pitch of a convex portion constituting the concavo-convex portion included in the pixel disposed in the peripheral portion of the pixel region.

In the solid-state imaging device according to the first aspect of the present technology, a pitch of a convex portion constituting the concavo-convex portion included in the pixel disposed in the central portion of the pixel region may be larger than a pitch of a convex portion constituting the concavo-convex portion included in the pixel disposed in the peripheral portion of the pixel region, the concavo-convex portion included in the pixel disposed in the central portion of the pixel region may be provided in an entire inner surface of the pixel when the pixel is seen in plan view, and the concavo-convex portion included in the pixel disposed in the peripheral portion of the pixel region may be provided in an entire inner surface of the pixel when the pixel is seen in plan view.

In the solid-state imaging device according to the first aspect of the present technology, the concavo-convex portion included in the pixel disposed in the central portion of the pixel region may have a point-symmetrical shape with a center of the concavo-convex portion as a point of symmetry when seen in plan view and have a rectangular shape, and the concavo-convex portion included in the pixel disposed in the peripheral portion of the pixel region may have a point-symmetrical shape with a center of the concavo-convex portion as a point of symmetry when seen in plan view and have a rectangular shape.

In the solid-state imaging device according to the first aspect of the present technology, the concavo-convex portion included in the pixel disposed in the central portion of the pixel region may have a point-symmetrical shape with a center of the concavo-convex portion as a point of symmetry when seen in plan view and have a rectangular shape, and the concavo-convex portion included in the pixel disposed in the peripheral portion of the pixel region may have a point-symmetrical shape with a center of the concavo-convex portion as a point of symmetry when seen in plan view and have a polygonal shape.

In the solid-state imaging device according to the first aspect of the present technology, a concavo-convex portion included in each pixel constituting the plurality of pixels may be provided to cover a light converging region in which the incident light formed in the photoelectric conversion unit converges.

In the solid-state imaging device according to the first aspect of the present technology, a position at which the concavo-convex portion included in the pixel disposed in the central portion of the pixel region is provided in the pixel when the pixel is seen in plan view may be different from a position at which the concavo-convex portion included in the pixel disposed in the peripheral portion of the pixel region is provided in the pixel when the pixel is seen in plan view.

In the solid-state imaging device according to the first aspect of the present technology, the concavo-convex portion included in the pixel disposed in the central portion of the pixel region may be provided at least in a center portion in the pixel when the pixel is seen in plan view, and the concavo-convex portion included in the pixel disposed in the peripheral portion of the pixel region may be provided to extend at least from the center portion in the pixel toward a peripheral portion without reaching a boundary portion between the pixel and an adjacent pixel when the pixel is seen in plan view.

In the solid-state imaging device according to the first aspect of the present technology, the concavo-convex portion included in the pixel disposed in the central portion of the pixel region may be provided at least in a center portion in the pixel when the pixel is seen in plan view, and a concavo-convex portion included in a pixel disposed in a right peripheral portion in the pixel region when the pixel region is seen in plan view may be provided to extend at least from the center portion in the pixel toward a left peripheral portion without reaching a boundary portion between the pixel and an adjacent pixel when the pixel is seen in plan view.

In the solid-state imaging device according to the first aspect of the present technology, the concavo-convex portion included in the pixel disposed in the central portion of the pixel region may be provided at least in a center portion in the pixel when the pixel is seen in plan view, and a concavo-convex portion included in a pixel disposed in a left peripheral portion in the pixel region when the pixel region is seen in plan view may be provided to extend at least from the center portion in the pixel toward a right peripheral portion without reaching a boundary portion between the pixel and an adjacent pixel when the pixel is seen in plan view.

Further, in the present technology, as a second aspect, provided is a solid-state imaging device including a pixel region in which a plurality of pixels are two-dimensionally disposed, in which each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view.

In the solid-state imaging device according to the second aspect of the present technology, the concavo-convex portion included in the pixel disposed in the central portion of the pixel region may be provided at least in a center portion in the pixel when the pixel is seen in plan view, and the concavo-convex portion included in the pixel disposed in the peripheral portion of the pixel region may be provided to extend at least from the center portion in the pixel toward a peripheral portion without reaching a boundary portion between the pixel and an adjacent pixel when the pixel is seen in plan view.

In the solid-state imaging device according to the second aspect of the present technology, the concavo-convex portion included in the pixel disposed in the central portion of the pixel region may be provided at least in a center portion in the pixel when the pixel is seen in plan view, and a concavo-convex portion included in a pixel disposed in a right peripheral portion in the pixel region when the pixel region is seen in plan view may be provided to extend at least from the center portion in the pixel toward a left peripheral portion without reaching a boundary portion between the pixel and an adjacent pixel when the pixel is seen in plan view.

In the solid-state imaging device according to the second aspect of the present technology, the concavo-convex portion included in the pixel disposed in the central portion of the pixel region may be provided at least in a center portion in the pixel when the pixel is seen in plan view, and a concavo-convex portion included in a pixel disposed in a left peripheral portion in the pixel region when the pixel region is seen in plan view may be provided to extend at least from the center portion in the pixel toward a right peripheral portion without reaching a boundary portion between the pixel and an adjacent pixel when the pixel is seen in plan view.

Further, in the present technology, provided is electronic equipment on which the solid-state imaging device according to the first aspect of the present technology or the solid-state imaging device according to the second aspect of the present technology is mounted.

According to the present technology, it is possible to further improve image quality and functionality of a solid-state imaging device. Meanwhile, the effects described herein are not necessarily limiting, and any of the effects described in the present disclosure may be obtained.

### BRIEF DESCRIPTION OF DRAWINGS

FIG. 1(a) to FIG. 1(c) are diagrams illustrating a configuration example of a solid-state imaging device according to a first embodiment to which the present technology is applied, and FIG. 1(d) is a diagram illustrating contrast unevenness in a pixel region.

FIG. 2(a) to FIG. 2(c) are diagrams illustrating a configuration example of a solid-state imaging device according to a second embodiment to which the present technology is applied, and FIG. 2(d) is a diagram illustrating contrast unevenness in a pixel region.

FIG. 3(a) is a diagram illustrating a configuration example of a solid-state imaging device according to a third embodiment to which the present technology is applied, and FIG. 3(b) is a diagram illustrating contrast unevenness in a pixel region.

FIG. 4(a) to FIG. 4(c) are diagrams illustrating a configuration example of the solid-state imaging device according to the third embodiment to which the present technology is applied, and FIG. 4(d) is a diagram illustrating contrast unevenness in a pixel region.

FIG. 5(a) to FIG. 5(c) are diagrams illustrating a configuration example of the solid-state imaging device according to the third embodiment to which the present technology is applied, and FIG. 5(d) is a diagram illustrating contrast unevenness in a pixel region.

FIG. 6 is a diagram illustrating a configuration example of a solid-state imaging device according to a fourth embodiment to which the present technology is applied.

FIG. 7(a) to FIG. 7(c) are diagrams illustrating a configuration example of the solid-state imaging device according to the fourth embodiment to which the present technology is applied, and FIG. 7(d) is a diagram illustrating contrast unevenness in a pixel region.

FIG. 8(a) is a diagram illustrating a configuration example of a solid-state imaging device according to a fifth embodiment to which the present technology is applied, and FIG. 8(b) is a diagram illustrating contrast unevenness in a pixel region.

FIG. 9(a) to FIG. 9(c) are diagrams illustrating a configuration example of the solid-state imaging device according to the fifth embodiment to which the present technology is applied, and FIG. 9(d) is a diagram illustrating contrast unevenness in a pixel region.

FIG. 10(a) to FIG. 10(c) are diagrams illustrating a configuration example of the solid-state imaging device according to the fifth embodiment to which the present technology is applied, and FIG. 10(d) is a diagram illustrating contrast unevenness in a pixel region.

FIG. 11 is a diagram illustrating a configuration example of four pixels included in a solid-state imaging device according to a sixth embodiment to which the present technology is applied.

FIG. 12 is a diagram illustrating a configuration example of four pixels included in a solid-state imaging device according to a seventh embodiment to which the present technology is applied.

FIG. 13 is a diagram illustrating an overall configuration example of the solid-state imaging device according to the first embodiment to which the present technology is applied.

FIG. 14 is a diagram illustrating an example of use of the solid-state imaging devices according to the first to seventh embodiments to which the present technology is applied.

FIG. 15 is a functional block diagram of an example of electronic equipment according to an eighth embodiment to which the present technology is applied.

FIG. 16 is a diagram illustrating an example of a schematic configuration of an endoscopic surgery system.

FIG. 17 is a block diagram illustrating examples of functional configurations of a camera head and a CCU.

FIG. 18 is a block diagram illustrating an example of a schematic configuration of a vehicle control system.

FIG. 19 is a diagram illustrating examples of positions at which a vehicle exterior information detection unit and an imaging unit are installed.

### DESCRIPTION OF EMBODIMENTS

Hereinafter, preferred embodiments for implementing the present technology will be described. The embodiments to be described below show an example of a representative embodiment of the present technology, and the scope of the present technology should not be narrowly construed based on this. Note that, in the drawings, unless otherwise specified, “up” means the upper direction or the upper side in the drawing, “down” means the lower direction or the lower side in the drawing, “left” means the left direction or the left side in the drawing, and “right” means the right direction or the right side in the drawing. Further, in the drawings, the same or equivalent elements or members are denoted by the same reference numerals and signs, and repeated description will be omitted.

The description will be made in the following order.

1. Outline of the present technology

2. First embodiment (Example 1 of solid-state imaging device)

3. Second embodiment (Example 2 of solid-state imaging device)

4. Third embodiment (Example 3 of solid-state imaging device)

5. Fourth embodiment (Example 4 of solid-state imaging device)

6. Fifth embodiment (Example 5 of solid-state imaging device)

7. Sixth embodiment (Example 6 of solid-state imaging device)

8. Seventh embodiment (Example 7 of solid-state imaging device)

9. Eighth embodiment (Example of electronic equipment)

10. Example of use of solid-state imaging device to which the present technology is applied

11. Example of application to endoscopic surgery system

12. Example of application to moving body

### 1. Outline of the Present Technology

First, an outline of the present technology will be described.

For example, in order to increase sensitivity characteristics of a single pixel (for example, one pixel), a convex-concave shape can be provided at an interface between a semiconductor substrate having a photoelectric conversion unit formed thereon and an insulating film. However, in an actual product, illuminance in a photoelectric conversion unit may differ in the plane of a chip (substrate) due to the influence of oblique incident light characteristics generated by an optical system such as a combination of lenses, and contrast unevenness may occur.

The present technology is contrived in view of the above-described circumstances. As a first aspect, the present technology can provide a solid-state imaging device including a pixel region in which a plurality of pixels are two-dimensionally disposed, in which each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and the number of irregularities of a concavo-convex portion included in a pixel disposed in a central portion of the pixel region and the number of irregularities of a concavo-convex portion included in a pixel disposed in a peripheral portion of the pixel region are different from each other. In addition, as a second aspect, the present technology can provide a solid-state imaging device including a pixel region in which a plurality of pixels are two-dimensionally disposed, in which each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view. According to the present technology, it is possible to manufacture a solid-state imaging device in which the uniformity of sensitivity in a chip surface or a substrate surface is increased. In addition, it is possible to reduce contrast unevenness reduction processing through gain adjustment of an analog circuit in a subsequent stage and signal processing by increasing the uniformity of sensitivity in the chip surface or the substrate surface.

Hereinafter, preferred embodiments for implementing the present technology will be described in detail with reference to the drawings. The embodiments to be described below show an example of a representative embodiment of the present technology, and the scope of the present technology should not be narrowly construed based on this.

### 2. First Embodiment (Example 1 of Solid-State Imaging Device)

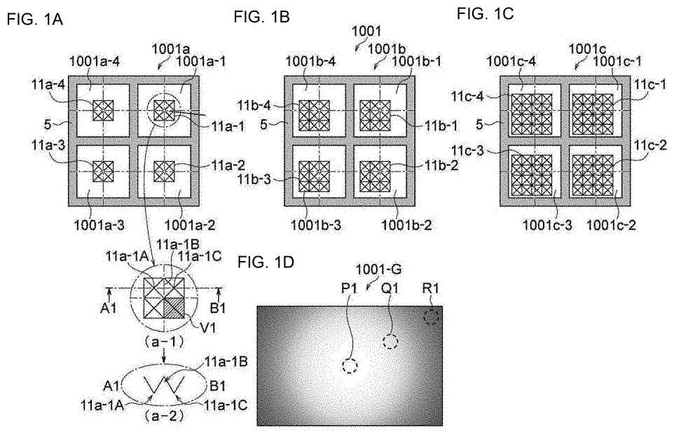

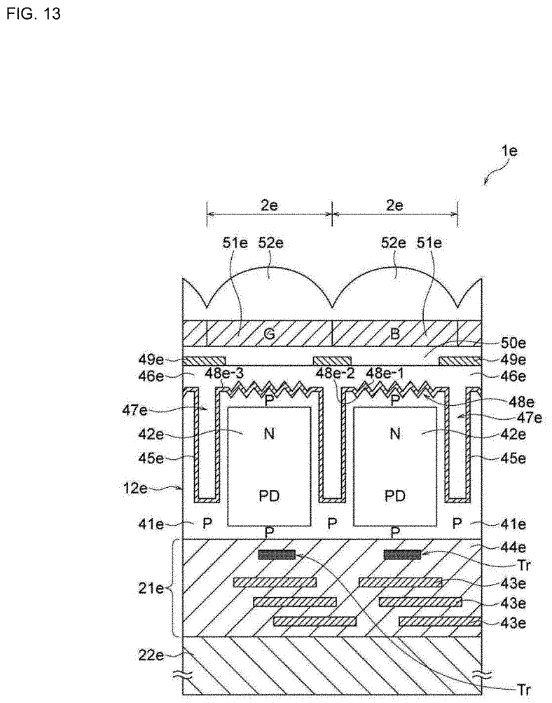

A solid-state imaging device according to a first embodiment (Example 1 of a solid-state imaging device) of the present technology will be described using FIGS. 1 and 13.

First, description will be made using FIG. 1. FIG. 1 is a diagram illustrating a configuration example of the solid-state imaging device according to the first embodiment of the present technology. In more detail, FIG. 1(a) is a plan view of a region 1001a corresponding to four pixels included in a solid-state imaging device 1001, FIG. 1(b) is a plan view of a region 1001b corresponding to four pixels included in the solid-state imaging device 1001, FIG. 1(c) is a plan view of a region 1001c corresponding to four pixels included in the solid-state imaging device 1001, and FIG. 1(d) is a diagram illustrating contrast unevenness in a pixel region 1001-G when seen in plan view from a light incident side.

As illustrated in FIG. 1(a), in the region 1001a corresponding to four pixels included in the solid-state imaging device 1001, four pixels 1001a-1 to 1001a-4 are formed in a clockwise order, and a light shielding film 5 is formed between the pixels (pixel boundary).

The region 1001a corresponding to four pixels is equivalent to a P1 region which is a central portion in the pixel region 1001-G illustrated in FIG. 1(d).

The pixel 1001a-1 includes a concavo-convex portion 11a-1, and the concavo-convex portion 11a-1 has a point-symmetrical shape with a pixel center t of the pixel 1001a-1 (see FIG. 1(a-1) to be described later; the same applies hereinafter) as a point of symmetry and has a rectangular shape. The pixel 1001a-2 includes a concavo-convex portion 11a-2, and the concavo-convex portion 11a-2 has a point-symmetrical shape with a pixel center t of the pixel 1001a-2 as a point of symmetry and has a rectangular shape. The pixel 1001a-3 includes a concavo-convex portion 11a-3, and the concavo-convex portion 11a-3 has a point-symmetrical shape with a pixel center t of the pixel 1001a-3 as a point of symmetry and has a rectangular shape. The pixel 1001a-4 includes a concavo-convex portion 11a-4, and the concavo-convex portion 11a-4 has a point-symmetrical shape with a pixel center t of the pixel 1001a-4 as a point of symmetry and has a rectangular shape. Note that the pixel center t corresponds to the center of each of the concavo-convex portions 11a-1 to 11a-4.

FIG. 1(a-1) is an enlarged plan view of a concavo-convex portion 11a-1 illustrated in FIG. 1(a), in which reference numerals 11a-1A and 11a-1C indicate a concave portion of a concavo-convex portion, and reference numeral 11a-1B indicates a convex portion of the concavo-convex portion. One pitch is a length from the concave portion 11a-1A to the concave portion 11a-1C. In addition, a half pitch is a length from the concave portion 11a-1A or the concave portion 11a-1C to the concavo-convex portion 11a-1B. Further, in the present specification, the range of an oblique line portion (the range indicated by reference numeral V1) in the concavo-convex portion 11a-1 is set as one unit of the concavo-convex portion, and represents the size of the concavo-convex portion when seen in plan view. Thus, the concavo-convex portion 11a-1 is constituted by four units. In addition, similarly, each of the concavo-convex portion 11a-2, a concavo-convex portion 11a-3, and a concavo-convex portion 11a-4 is four units. Each of a concavo-convex portion 11b-1, a concavo-convex portion 11b-2, a concavo-convex portion 11b-3, and a concavo-convex portion 11b-4 to be described below is nine units in FIG. 1(b), and each of a concavo-convex portion 11c-1, a concavo-convex portion 11c-2, a concavo-convex portion 11c-3, and a concavo-convex portion 11c-4 is 16 units in FIG. 1(c).

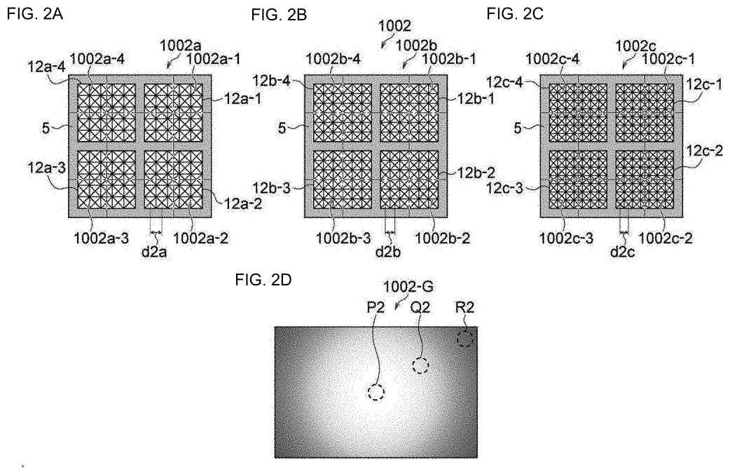

FIG. 1(a-2) is a cross-sectional view taken along line A1-B1 illustrated in FIG. 1(a-1). As illustrated in FIG. 1(a-2), a convex portion 11a-1B of the concavo-convex portion 11a-1 has a triangular pyramid shape (triangle when seen in a cross-sectional view). Note that a concavo-convex portion 17a-1 can be manufactured by wet etching.

The concavo-convex portions 11a-1 to 11a-4 are formed in the center portion (a region surrounding the pixel center t) of each of the pixels 1001a-1 to 1001a-4, and thus it is possible to prevent the reflection of vertically incident light and efficiently confine light to improve quantum efficiency. In addition, the concavo-convex portions 11a-1 to 11a-4 are not formed to the light shielding film 5 between the pixels, and a flat portion is formed on a peripheral edge of each of the four pixels 1001a-1 to 1001a-4, and thus scattering may not occur due to the concavo-convex portion. In this case, there is no light leakage to the adjacent pixels, and thus color mixing can be prevented.

As illustrated in FIG. 1(b), four pixels 1001b-1 to 1001b-4 are formed in a clockwise order in the region 1001b corresponding to four pixels included in the solid-state imaging device 1001, and the light shielding film 5 is formed between the pixels (pixel boundary).

The region 1001b corresponding to four pixels is equivalent to a Q1 region which is a right upper peripheral portion in the pixel region 1001-G illustrated in FIG. 1(d).

The pixel 1001b-1 includes a concavo-convex portion 11b-1, and the concavo-convex portion 11b-1 has a point-symmetrical shape with the center of the concavo-convex portion 11b-1 as a point of symmetry and has a rectangular shape. The pixel 1001b-2 includes a concavo-convex portion 11b-2, and the concavo-convex portion 11b-2 has a point-symmetrical shape with the center of the concavo-convex portion 11b-2 as a point of symmetry and has a rectangular shape. The pixel 1001b-3 includes a concavo-convex portion 11b-3, and the concavo-convex portion 11b-3 has a point-symmetrical shape with the center of the concavo-convex portion 11b-3 as a point of symmetry and has a rectangular shape. The pixel 1001b-4 includes a concavo-convex portion 11b-4, and the concavo-convex portion 11b-4 has a point-symmetrical shape with the center of the concavo-convex portion 11b-4 as a point of symmetry and has a rectangular shape. In addition, the number of irregularities of the concavo-convex portions 11b-1 to 11b-4 is larger than the number of irregularities of the concavo-convex portions 11a-1 to 11a-4. By increasing the number of irregularities of the concavo-convex portions 11b-1 to 11b-4, it is possible to increase sensitivity by more effectively preventing the reflection of right oblique light incident in the Q1 region.

Each of the concavo-convex portions 11b-1 to 11b-4 is mainly formed in a left lower portion of the pixel (a left upper portion of the pixel may also be used) with respect to the pixel center t of each of the pixels 1001b-1 to 1001b-4, and thus it is possible to prevent the reflection of right oblique incident light and efficiently confine light to improve the quantum efficiency. In a case where the concavo-convex portion is mainly formed in the right lower portion (or right upper portion) of the pixel, it is possible to prevent the reflection of left oblique incident light and efficiently confine light to improve quantum efficiency. In addition, the concavo-convex portions 11b-1 to 11b-4 are not formed to the light shielding film 5 between the pixels, and a flat portion is formed on a peripheral edge of each of the four pixels 1001b-1 to 1001b-4, and thus scattering may not occur due to the concavo-convex portion. In this case, there is no light leakage to the adjacent pixels, and thus color mixing can be prevented.

As illustrated in FIG. 1(c), four pixels 1001c-1 to 1001c-4 are formed in a clockwise order in the region 1001c corresponding to four pixels included in the solid-state imaging device 1001, and the light shielding film 5 is formed between the pixels (pixel boundary).

The region 1001c corresponding to four pixels is equivalent to an R1 region which is a right upper peripheral edge (the vicinity of a right upper vertex portion in the pixel region 1001-G) of the right upper peripheral portion in the pixel region 1001-G illustrated in FIG. 1(d).

The pixel 1001c-1 includes a concavo-convex portion 11c-1, and the concavo-convex portion 11c-1 has a point-symmetrical shape with the center of the concavo-convex portion 11c-1 as a point of symmetry and has a rectangular shape. The pixel 1001c-2 includes a concavo-convex portion 11c-2, and the concavo-convex portion 11c-2 has a point-symmetrical shape with the center of the concavo-convex portion 11c-2 as a point of symmetry and has a rectangular shape. The pixel 1001c-3 includes a concavo-convex portion 11c-3, and the concavo-convex portion 11c-3 has a point-symmetrical shape with the center of the concavo-convex portion 11c-3 as a point of symmetry and has a rectangular shape. The pixel 1001c-4 includes a concavo-convex portion 11c-4, and the concavo-convex portion 11c-4 has a point-symmetrical shape with the center of the concavo-convex portion 11c-4 as a point of symmetry and has a rectangular shape. In addition, the number of irregularities of the concavo-convex portions 11c-1 to 11c-4 is larger than the number of irregularities of the concavo-convex portions 11b-1 to 11b-4. By increasing the number of irregularities of the concavo-convex portions 11c-1 to 11c-4, it is possible to increase sensitivity by more effectively preventing the reflection of right oblique light incident in the R1 region.

Each of the concavo-convex portions 11c-1 to 11c-4 is mainly formed in a left lower portion of the pixel (a left upper portion of the pixel may also be used) with respect to the pixel center t of each of the pixels 1001c-1 to 1001c-4, and thus it is possible to prevent the reflection of right oblique incident light and efficiently confine light to improve the quantum efficiency. In a case where the concavo-convex portion is mainly formed in the right lower portion (or right upper portion) of the pixel, it is possible to prevent the reflection of left oblique incident light and efficiently confine light to improve quantum efficiency. In addition, the concavo-convex portions 11c-1 to 11c-4 are not formed to the light shielding film 5 between the pixels, and a flat portion is formed on a peripheral edge of each of the four pixels 1001c-1 to 1001c-4, and thus scattering may not occur due to the concavo-convex portion. In this case, there is no light leakage to the adjacent pixels, and thus color mixing can be prevented.

As described above, the number of irregularities of the concavo-convex portion increases from the P1 region (the center portion of the pixel region) to the Q1 region and the R1 region, and it is possible to achieve the uniformity of sensitivity in the chip (in the substrate). That is, it is possible to improve contrast unevenness illustrated in FIG. 1(d) by the solid-state imaging device according to the first embodiment (Example 1 of a solid-state imaging device) of the present technology.

Next, description will be made using FIG. 13. FIG. 13 is a diagram illustrating a configuration example of a solid-state imaging device according to the first embodiment of the present technology, and more specifically, is a cross-sectional view of a pixel 2e (two pixels are illustrated in the drawing) of a solid-state imaging device 1e. Note that a configuration example of the solid-state imaging device 1e can be applied to solid-state imaging devices of second to seventh embodiments according to the present technology to be described later, unless there is no particular technical contradiction.

The solid-state imaging device 1e includes a semiconductor substrate 12e, a multilayer wiring layer 21e formed on the surface side thereof (the lower side in the drawing), and a support substrate 22e.

The semiconductor substrate 12e is formed of, for example, silicon (Si), and is formed to have a thickness of, for example, 1 to 6 μm. In the semiconductor substrate 12e, for example, an N-type (second conductive type) semiconductor region 42e is formed for each pixel 2e in a P-type (first conductive type) semiconductor region 41e, and thus a photodiode PD is formed in pixel units. The P-type semiconductor region 41e facing both the front and back surfaces of the semiconductor substrate 12e also serves as a hole charge storage region for suppressing a dark current.

Note that the P-type semiconductor region 41e is deeply dug as illustrated in FIG. 13 at a pixel boundary of each pixel 2e between the N-type semiconductor regions 42e in order to form an inter-pixel light shielding portion 47e. The inter-pixel light shielding portion 47e has an effect of reflecting incident light scattered by a concavo-convex portion 48e (antireflection portion) and confining the incident light in the photoelectric conversion unit (photodiode (PD)).

An interface (an interface on a light receiving surface) of the P-type semiconductor region 41e above an N-type semiconductor region 42e serving as a charge storage region constitutes an antireflection portion 48e that prevents the reflection of incident light by a so-called moth-eye structure in which minute concavo-convex portions (concavo-convex structures) are formed. That is, the antireflection portion (concavo-convex portion) 48e includes a convex portion 48e-1 and a concave portion 48e-2. In the antireflection portion 48e, a pitch of a convex portion of a triangular pyramid shape (triangle when seen in a cross-sectional view) which is equivalent to the cycle of irregularities is set to be, for example, in the range of 40 nm to 200 nm.

The multilayer wiring layer 21e includes a plurality of wiring layers 43e and an interlayer insulating film 44e. In addition, a plurality of pixel transistors Tr that perform read-out of charge accumulated in the photodiode PD, and the like are also formed in the multilayer wiring layer 21e (at an interface between the multilayer wiring layer 21e and the semiconductor substrate 12e).

A pinning layer 45e is formed on the back surface side of the semiconductor substrate 12e so as to cover the upper surface of the P-type semiconductor region 41e. The pinning layer 45e is formed using a high dielectric having a negative fixed charge so that a positive charge (hole) storage region is formed at an interface with the semiconductor substrate 12e and the generation of a dark current is suppressed. When the pinning layer 45e is formed to have a negative fixed charge, an electric field is applied to the interface with the semiconductor substrate 12e by the negative fixed charge, and thus a hole charge storage region is formed.

The pinning layer 45e is formed using, for example, hafnium oxide (HfO₂). In addition, the pinning layer 45e is formed using zirconium dioxide (ZrO₂), tantalum pentoxide (Ta₂O₅), or the like.

A transparent insulating film 46e is embedded in a dug portion of the P-type semiconductor region 41e and is formed on the entire back surface side of the upper portion of the pinning layer 45e of the semiconductor substrate 12e. The dug portion of the P-type semiconductor region 41e having the transparent insulating film 46e embedded therein constitutes the inter-pixel light shielding portion 47e that prevents leakage of incident light (for example, incident light scattered by the antireflection portion 48) from the adjacent pixel 2e. In addition, a flat portion 48e-3 constituted by the pinning layer 45e is formed between the inter-pixel light shielding portion 47e and the antireflection portion 48e, light leakage to the adjacent pixels is less likely to occur by forming the flat portion 48e-3, and thus color mixing can be further prevented.

The transparent insulating film 46e is a material that transmits light, has an insulating property, and has a refractive index n1 smaller than a refractive index n2 of the semiconductor region 41e and the semiconductor region 42e (n1<n2). As a material of the transparent insulating film 46e, silicon oxide (SiO₂), silicon nitride (SiN), silicon oxynitride (SiON), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), placeodim oxide (Pr₂O₃), cerium oxide (CeO₂), neoclim oxide (Nd₂O₃), promethium oxide (Pm₂O₃), samalium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), yttrium oxide (Y₂O₃), a resin, and the like can be used alone or in combination.

Note that an antireflection film may be laminated on the upper side of the pinning layer 45e before the transparent insulating film 46e is formed. As a material of the antireflection film, silicon nitride (SiN), hafnium oxide (HfO₂), aluminum oxide (Al₂O₃), zirconium oxide (ZrO₂), tantalum oxide (Ta₂Ta5), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samalium oxide (Sm₂O₃), europium oxide (Eu₂O₃), gadolinium oxide (Gd₂O₃), terbium oxide (Tb₂O₃), dysprosium oxide (Dy2O₃), holmium oxide (Ho₂O₃), thulium oxide (Tm₂O₃), ytterbium oxide (Yb₂O₃), lutetium oxide (Lu₂O₃), yttrium oxide (Y₂O₃), and the like can be used.

The antireflection film may be formed on only the upper surface of the antireflection portion 48e of the moth-eye structure, or may be formed on both the upper surface of the antireflection portion 48e and the side surface of the inter-pixel light shielding portion 47e, similar to the pinning layer 45e.

A light shielding film 49e is formed in a region of a pixel boundary on the transparent insulating film 46e. As a material of the light shielding film 49e, a material that shields light may be used, and for example, tungsten (W), aluminum (Al), copper (Cu), and the like can be used.

A flattened film 50e is formed on the entire upper surface side of the transparent insulating film 46e including the light shielding film 49e. As a material of the flattened film 50e, an organic material such as a resin can be used.

A color filter layers 51e of red, green, or blue is formed for each pixel above the flattened film 50e. The color filter layer 51e is formed by rotationally applying a photosensitive resin containing a dye such as a pigment or a dye. Red, green, and blue colors are disposed by, for example, a Bayer arrangement, but may be disposed by other arrangement methods. In the example of FIG. 13, the color filter layer 51e of Blue (B) is formed in the pixel 2e on the right side, and the color filter layer 51e of Green (G) is formed in the pixel 2e on the left side. An on-chip lens 52e is formed for each pixel 2e above the color filter layer 51e. The on-chip lens 52e is formed of a resin-based material such as a styrene-based resin, an acrylic-based resin, a styrene-acrylic copolymer resin, or a siloxane-based resin. Incident light converges on the on-chip lens 52e, and the converged light is efficiently incident on the photocliode PD through the color filter layer 51e.

A method of manufacturing the concavo-convex portion 48e will be described.

A photoresist is applied to the upper surface of the semiconductor substrate 12e on the back surface side, and the photoresist is patterned by lithography technology so that a concave portion of the moth-eye structure of the antireflection portion (concavo-convex portion) 48e is opened.

By performing wet etching processing on the semiconductor substrate 12e on the basis of the patterned photoresist, the concave portion of the moth-eye structure of the antireflection portion 48e is formed, and then the photoresist is removed. Note that, in a case where a convex portion has a spindle shape, the moth-eye structure of the antireflection portion 48e can be formed by dry etching processing, and in a case where a convex portion has a triangular pyramid shape as illustrated in FIG. 13, the moth-eye structure can be formed by wet etching processing as described above.

Next, the pinning layer (metal oxide film) 45e is formed on the entire surface (back surface) of the semiconductor substrate 12e by, for example, a chemical vapor deposition (CVD) method, the semiconductor substrate 12e having the antireflection portion 48e of the moth-eye structure and a trench structure 47e formed therein.

In addition, the insulating film 46e is formed on the upper surface of the pinning layer (metal oxide film) 45e using a film formation method having a high embedding property such as a CVD method.

The above-described contents of the solid-state imaging device according to the first embodiment (Example 1 of a solid-state imaging device) of the present technology can be applied to solid-state imaging devices according to second to seventh embodiments of the present technology to be described later, unless there is no particular technical contradiction.

### 3. Second Embodiment (Example 2 of Solid-State Imaging Device)

A solid-state imaging device according to a second embodiment (Example 2 of a solid-state imaging device) of the present technology will be described using FIG. 2. FIG. 2 is a diagram illustrating a configuration example of the solid-state imaging device according to the second embodiment of the present technology. In more detail, FIG. 2(a) is a plan view of a region 1002a corresponding to four pixels included in a solid-state imaging device 1002, FIG. 2(b) is a plan view of a region 1002b corresponding to four pixels included in the solid-state imaging device 1002, FIG. 2(c) is a plan view of a region 1002c corresponding to four pixels included in the solid-state imaging device 1002, and FIG. 2(d) is a diagram illustrating contrast unevenness in a pixel region 1002-G when seen in plan view from a light incident side.

As illustrated in FIG. 2(a), four pixels 1002a-1 to 1002a-4 are formed in a clockwise order in the region 1002a corresponding to four pixels included in the solid-state imaging device 1002, and a light shielding film 5 is formed between the pixels (pixel boundary).

The region 1002a corresponding to four pixels is equivalent to a P2 region which is a central portion of the pixel region 1002-G illustrated in FIG. 2(d).

The pixel 1002a-1 includes a concavo-convex portion 12a-1, and the concavo-convex portion 12a-1 has a point-symmetrical shape with a pixel center t of the pixel 1002a-1 as a point of symmetry and has a rectangular shape. The pixel 1002a-2 includes a concavo-convex portion 12a-2, and the concavo-convex portion 12a-2 has a point-symmetrical shape with a pixel center t of the pixel 1002a-2 as a point of symmetry and has a rectangular shape. The pixel 1002a-3 includes a concavo-convex portion 12a-3, and the concavo-convex portion 12a-3 has a point-symmetrical shape with a pixel center t of the pixel 1002a-3 as a point of symmetry and has a rectangular shape. The pixel 1002a-4 includes a concavo-convex portion 12a-4, and the concavo-convex portion 12a-4 has a point-symmetrical shape with a pixel center t of the pixel 1002a-4 as a point of symmetry and has a rectangular shape. The concavo-convex portions 12a-1 to 12a-4 are formed in all pixels of each of the four pixels 1002a-1 to 1002a-4. Note that the pixel center t corresponds to the center of each of the concavo-convex portions 12a-1 to 12a-4.

As illustrated in FIG. 2(b), four pixels 1002b-1 to 1002b-4 are formed in a clockwise order in the region 1002b corresponding to four pixels included in the solid-state imaging device 1002, and the light shielding film 5 is formed between the pixels (pixel boundary).

The region 1002b corresponding to four pixels is equivalent to a Q2 region which is a right upper peripheral portion in the pixel region 1002-G illustrated in FIG. 2(d).

The pixel 1002b-1 includes a concavo-convex portion 12b-1, and the concavo-convex portion 12b-1 has a point-symmetrical shape with a pixel center t of the pixel 1002b-1 as a point of symmetry and has a rectangular shape. The pixel 1002b-2 includes a concavo-convex portion 12b-2, and the concavo-convex portion 12b-2 has a point-symmetrical shape with a pixel center t of the pixel 1002b-2 as a point of symmetry and has a rectangular shape. The pixel 1002b-3 includes a concavo-convex portion 12b-3, and the concavo-convex portion 12b-3 has a point-symmetrical shape with a pixel center t of the pixel 1002b-3 as a point of symmetry and has a rectangular shape. The pixel 1002b-4 includes a concavo-convex portion 12b-4, and the concavo-convex portion 12b-4 has a point-symmetrical shape with a pixel center t of the pixel 1002b-4 as a point of symmetry and has a rectangular shape. The concavo-convex portions 12b-1 to 12b-4 are formed in all pixels of each of the four pixels 1002b-1 to 1002b-4. Note that the pixel center t corresponds to the center of each of the concavo-convex portions 12b-1 to 12b-4. As illustrated in FIGS. 2(a) and 2(b), a pitch (d2b) of each of the concavo-convex portions 12b-1 to 12b-4 is smaller than a pitch (d2a) of each of the concavo-convex portions 12a-1 to 12a-4, and the number of pitches (d2b) is larger than the number of pitches (d2a). By shortening the pitch of each of the concavo-convex portions 12b-1 to 12b-4 and increasing the number of pitches, it is possible to increase sensitivity by more effectively preventing the reflection of right oblique light incident in the Q2 region.

As illustrated in FIG. 2(c), four pixels 1002c-1 to 1002c-4 are formed in a clockwise order in the region 1002c corresponding to four pixels included in the solid-state imaging device 1002, and the light shielding film 5 is formed between the pixels (pixel boundary).

The region 1002c corresponding to four pixels is equivalent to an R2 region which is a right upper peripheral edge (the vicinity of a right upper vertex portion in the pixel region 1002-G) of the right upper peripheral portion in the pixel region 1002-G illustrated in FIG. 2(d).

The pixel 1002c-1 includes a concavo-convex portion 12c-1, and the concavo-convex portion 12c-1 has a point-symmetrical shape with a pixel center t of the pixel 1002c-1 as a point of symmetry and has a rectangular shape. The pixel 1002c-2 includes a concavo-convex portion 12c-2, and the concavo-convex portion 12c-2 has a point-symmetrical shape with a pixel center t of the pixel 1002c-2 as a point of symmetry and has a rectangular shape. The pixel 1002c-3 includes a concavo-convex portion 12c-3, and the concavo-convex portion 12c-3 has a point-symmetrical shape with a pixel center t of the pixel 1002c-3 as a point of symmetry and has a rectangular shape. The pixel 1002c-4 includes a concavo-convex portion 12c-4, and the concavo-convex portion 12c-4 has a point-symmetrical shape with a pixel center t of the pixel 1002c-4 as a point of symmetry and has a rectangular shape. The concavo-convex portions 12c-1 to 12c-4 are formed in all pixels of each of the four pixels 1002c-1 to 1002c-4. Note that the pixel center t corresponds to the center of each of the concavo-convex portions 12c-1 to 12c-4. As illustrated in FIGS. 2(b) and 2(c), a pitch (d2c) of each of the concavo-convex portions 12c-1 to 12c-4 is smaller than a pitch (d2b) of each of the concavo-convex portions 12b-1 to 12b-4, and the number of pitches (d2c) is larger than the number of pitches (d2b). By shortening the pitch of each of the concavo-convex portions 12c-1 to 12c-4 and increasing the number of pitches, it is possible to increase sensitivity by more effectively preventing the reflection of right oblique light incident in the R2 region.

As described above, the number of pitches of the concavo-convex portion increases from the P2 region (the center portion of the pixel region) to the Q2 region and the R2 region (the right peripheral portion in the pixel region), and it is possible to achieve the uniformity of sensitivity in the chip (in the substrate). That is, it is possible to improve contrast unevenness illustrated in FIG. 2(d) by the solid-state imaging device according to the second embodiment (Example 2 of a solid-state imaging device) of the present technology.

The above-described contents of the solid-state imaging device according to the second embodiment (Example 2 of a solid-state imaging device) of the present technology can be applied to the above-described solid-state imaging device according to the first embodiment of the present technology and solid-state imaging devices to be described later according to third to seventh embodiments of the present technology, unless there is no particular technical contradiction.

### 4. Third Embodiment (Example 3 of Solid-State Imaging Device)

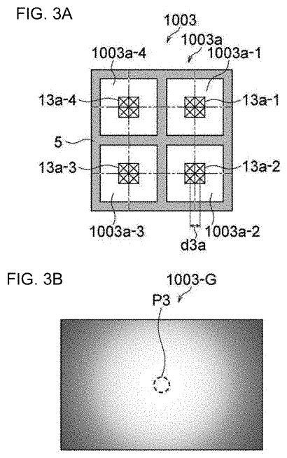

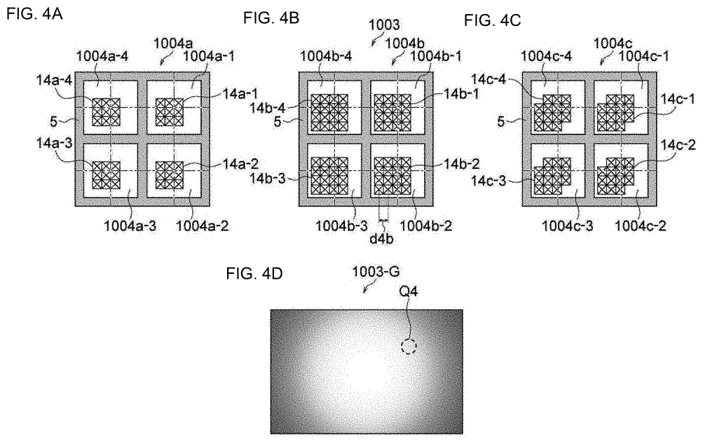

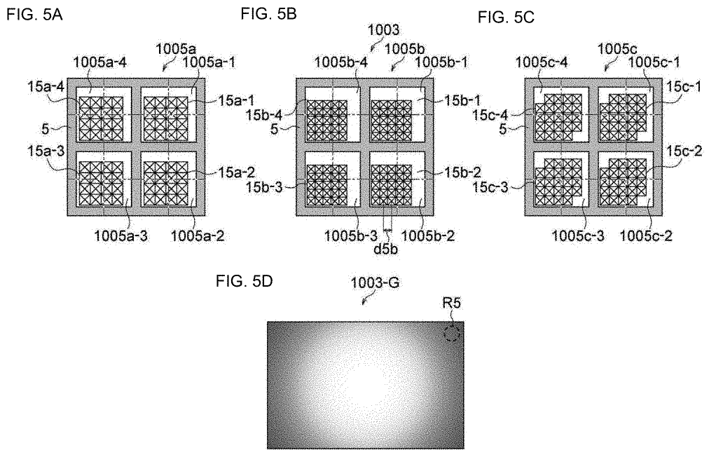

A solid-state imaging device according to a third embodiment (Example 3 of a solid-state imaging device) of the present technology will be described using FIGS. 3 to 5. FIG. 3 is a diagram illustrating a configuration example of a solid-state imaging device according to the third embodiment of the present technology. In more detail, FIG. 3(a) is a plan view of a region 1003a corresponding to four pixels included in a solid-state imaging device 1003, and FIG. 3(b) is a diagram illustrating contrast unevenness in a pixel region 1003-G. FIG. 4 is a diagram illustrating a configuration example of the solid-state imaging device according to the third embodiment of the present technology. In more detail, FIG. 4(a) is a plan view of a region 1004a corresponding to four pixels included in the solid-state imaging device 1003, FIG. 4(b) is a plan view of a region 1004b corresponding to four pixels included in the solid-state imaging device 1003, FIG. 4(c) is a plan view of a region 1004c corresponding to four pixels included in the solid-state imaging device 1003, and FIG. 4(d) is a diagram illustrating contrast unevenness in a pixel region 1003-G. FIG. 5 is a diagram illustrating a configuration example of the solid-state imaging device according to the third embodiment of the present technology. In more detail, FIG. 5(a) is a plan view of a region 1005a corresponding to four pixels included in the solid-state imaging device 1003, FIG. 5(b) is a plan view of a region 1005b corresponding to four pixels included in the solid-state imaging device 1003, FIG. 5(c) is a plan view of a region 1005c corresponding to four pixels included in the solid-state imaging device 1003, and FIG. 5(d) is a diagram illustrating contrast unevenness in the pixel region 1003-G.

As illustrated in FIG. 3(a), in the region 1003a corresponding to four pixels included in the solid-state imaging device 1003, four pixels 1003a-1 to 1003a-4 are formed in a clockwise order, and a light shielding film 5 is formed between the pixels (pixel boundary).

The region 1003a corresponding to four pixels is equivalent to a P3 region which is a central portion in the pixel region 1003-G illustrated in FIG. 3(b).

The pixel 1003a-1 includes a concavo-convex portion 13a-1, and the concavo-convex portion 13a-1 has a point-symmetrical shape with a pixel center t of the pixel 1003a-1 as a point of symmetry and has a rectangular shape. The pixel 1003a-2 includes a concavo-convex portion 13a-2, and the concavo-convex portion 13a-2 has a point-symmetrical shape with a pixel center t of the pixel 1003a-2 as a point of symmetry and has a rectangular shape. The pixel 1003a-3 includes a concavo-convex portion 13a-3, and the concavo-convex portion 13a-3 has a point-symmetrical shape with a pixel center t of the pixel 1003a-3 as a point of symmetry and has a rectangular shape. The pixel 1003a-4 includes a concavo-convex portion 13a-4, and the concavo-convex portion 13a-4 has a point-symmetrical shape with a pixel center t of the pixel 1003a-4 as a point of symmetry and has a rectangular shape. Note that the pixel center t corresponds to the centers of the concavo-convex portions 13a-1 to 13a-4.

The concavo-convex portions 13a-1 to 13a-4 are formed in center portions (regions surrounding the pixel centers t) of the respective pixels 1003a-1 to 1003a-4, and thus it is possible to prevent the reflection of vertically incident light and efficiently confine vertically incident light to improve quantum efficiency. In addition, the concavo-convex portions 13a-1 to 13a-4 are not formed to the light shielding film 5 between the pixels, and a flat portion is formed on a peripheral edge of each of the four pixels 1003a-1 to 1003a-4, and thus scattering may not occur due to the concavo-convex portion. In this case, there is no light leakage to the adjacent pixels, and thus color mixing can be prevented.

As illustrated in FIG. 4(a), four pixels 1004a-1 to 1004a-4 are formed in a clockwise order in the region 1004a corresponding to four pixels included in the solid-state imaging device 1003, and the light shielding film 5 is formed between the pixels (pixel boundary).

The region 1004a corresponding to four pixels is equivalent to the Q4 region which is a right upper peripheral portion in the pixel region 1004-G illustrated in FIG. 4(d).

The pixel 1004a-1 includes a concavo-convex portion 14a-1, and the concavo-convex portion 14a-1 has a point-symmetrical shape with the center of the concavo-convex portion 14a-1 as a point of symmetry and has a rectangular shape. The pixel 1004a-2 includes a concavo-convex portion 14a-2, and the concavo-convex portion 14a-2 has a point-symmetrical shape with the center of the concavo-convex portion 14a-2 as a point of symmetry and has a rectangular shape. The pixel 1004a-3 includes a concavo-convex portion 14a-3, and the concavo-convex portion 14a-3 has a point-symmetrical shape with the center of the concavo-convex portion 14a-3 as a point of symmetry and has a rectangular shape. The pixel 1004a-4 includes a concavo-convex portion 14a-4, and the concavo-convex portion 14a-4 has a point-symmetrical shape with the center of the concavo-convex portion 14a-4 as a point of symmetry and has a rectangular shape. In addition, the number of irregularities of the concavo-convex portions 14a-1 to 14a-4 is larger than the number of irregularities of the concavo-convex portions 13a-1 to 13a-4.

Each of the concavo-convex portions 14a-1 to 14a-4 is mainly formed in a left lower portion of the pixel with respect to the pixel center t of each of the pixels 1004a-1 to 1004a-4, and thus it is possible to prevent the reflection of right oblique incident light and efficiently confine light to improve the quantum efficiency. In addition, the concavo-convex portions 14a-1 to 14a-4 are not formed to the light shielding film 5 between the pixels, and a flat portion is formed on a peripheral edge of each of the four pixels 1004a-1 to 1004a-4, and thus scattering may not occur due to the concavo-convex portion. In this case, there is no light leakage to the adjacent pixels, and thus color mixing can be prevented.

As illustrated in FIG. 4(b), four pixels 1004b-1 to 1004b-4 are formed in a clockwise order in the region 1004b corresponding to four pixels included in the solid-state imaging device 1003, and the light shielding film 5 is formed between the pixels (pixel boundary).

The region 1004b corresponding to four pixels is equivalent to a Q4 region which is a right upper peripheral portion in the pixel region 1004-G illustrated in FIG. 4(d).

The pixel 1004b-1 includes a concavo-convex portion 14b-1, and the concavo-convex portion 14b-1 has a point-symmetrical shape with the center of the concavo-convex portion 14b-1 as a point of symmetry and has a rectangular shape. The pixel 1004b-2 includes a concavo-convex portion 14b-2, and the concavo-convex portion 14b-2 has a point-symmetrical shape with the center of the concavo-convex portion 14b-2 as a point of symmetry and has a rectangular shape. The pixel 1004b-3 includes a concavo-convex portion 14b-3, and the concavo-convex portion 14b-3 has a point-symmetrical shape with the center of the concavo-convex portion 14b-3 as a point of symmetry and has a rectangular shape. The pixel 1004b-4 includes a concavo-convex portion 14b-4, and the concavo-convex portion 14b-4 has a point-symmetrical shape with the center of the concavo-convex portion 14b-4 as a point of symmetry and has a rectangular shape. In addition, a pitch (d4b) of each of the concavo-convex portions 14b-1 to 14b-4 is smaller than a pitch (d3a) of each of the concavo-convex portions 13a-1 to 13a-4, and the number of irregularities of each of the concavo-convex portions 14b-1 to 14b-4 is larger than the number of irregularities of each of the concavo-convex portions 13a-1 to 13a-4.

Each of the concavo-convex portions 14b-1 to 14b-4 is mainly formed in a left lower portion of the pixel with respect to the pixel center t of each of the pixels 1004b-1 to 1004b-4, and thus it is possible to prevent the reflection of right oblique incident light and efficiently confine light to improve the quantum efficiency. In addition, the concavo-convex portions 14b-1 to 14b-4 are not formed to the light shielding film 5 between the pixels, and a flat portion is formed on a peripheral edge of each of the four pixels 1004b-1 to 1004b-4, and thus scattering may not occur due to the concavo-convex portion. In this case, there is no light leakage to the adjacent pixels, and thus color mixing can be prevented.

As illustrated in FIG. 4(c), four pixels 1004c-1 to 1004c-4 are formed in a clockwise order in the region 1004c corresponding to four pixels included in the solid-state imaging device 1003, and the light shielding film 5 is formed between the pixels (pixel boundary).

The region 1004c corresponding to four pixels is equivalent to the Q4 region which is a right upper peripheral portion in the pixel region 1004-G illustrated in FIG. 4(d).

The pixel 1004c-1 includes a concavo-convex portion 14c-1, and the concavo-convex portion 14c-1 has a point-symmetrical shape with the center of the concavo-convex portion 14c-1 as a point of symmetry and has a polygonal shape. The pixel 1004c-2 includes a concavo-convex portion 14c-2, and the concavo-convex portion 14c-2 has a point-symmetrical shape with the center of the concavo-convex portion 14c-2 as a point of symmetry and has a polygonal shape. The pixel 1004c-3 includes a concavo-convex portion 14c-3, and the concavo-convex portion 14c-3 has a point-symmetrical shape with the center of the concavo-convex portion 14c-3 as a point of symmetry and has a polygonal shape. The pixel 1004c-4 includes a concavo-convex portion 14c-4, and the concavo-convex portion 14c-4 has a point-symmetrical shape with the center of the concavo-convex portion 14c-4 as a point of symmetry and has a polygonal shape. Note that each of the concavo-convex portions 14c-1 to 14c-4 has a point-symmetrical shape with the center of each of the concavo-convex portions as a point of symmetry, but may have an asymmetrical shape.

Each of the concavo-convex portions 14c-1 to 14c-4 is mainly formed in a left lower portion of the pixel with respect to the pixel center t of each of the pixels 1004c-1 to 1004c-4, and thus it is possible to prevent the reflection of right oblique incident light and efficiently confine light to improve the quantum efficiency. In addition, the concavo-convex portions 14c-1 to 14c-4 are not formed to the light shielding film 5 between the pixels, and a flat portion is formed on a peripheral edge of each of the four pixels 1004c-1 to 1004c-4, and thus scattering may not occur due to the concavo-convex portion. In this case, there is no light leakage to the adjacent pixels, and thus color mixing can be prevented. Since each of the concavo-convex portions 14c-1 to 14c-4 has a polygonal shape, the concavo-convex portion more efficiently covers a light converging region of right oblique incident light and efficiently confines light to improve a quantum effect, thereby further contributing to the uniformity of sensitivity in the chip (in the substrate).

As illustrated in FIG. 5(a), in the region 1005a corresponding to four pixels included in the solid-state imaging device 1003, four pixels 1005a-1 to 1005a-4 are formed in a clockwise order, and the light shielding film 5 is formed between the pixels (pixel boundary).

The region 1005a corresponding to four pixels is equivalent to an R5 region which is a right upper peripheral edge (the vicinity of a right upper vertex portion in the pixel region 1005-G) of the right upper peripheral portion in the pixel region 1005-G illustrated in FIG. 5(d).

The pixel 1005a-1 includes a concavo-convex portion 15a-1, and the concavo-convex portion 15a-1 has a point-symmetrical shape with the center of the concavo-convex portion 15a-1 as a point of symmetry and has a rectangular shape. The pixel 1005a-2 includes a concavo-convex portion 15a-2, and the concavo-convex portion 15a-2 has a point-symmetrical shape with the center of the concavo-convex portion 15a-2 as a point of symmetry and has a rectangular shape. The pixel 1005a-3 includes a concavo-convex portion 15a-3, and the concavo-convex portion 15a-3 has a point-symmetrical shape with the center of the concavo-convex portion 15a-3 as a point of symmetry and has a rectangular shape. The pixel 1005a-4 includes a concavo-convex portion 15a-4, and the concavo-convex portion 15a-4 has a point-symmetrical shape with the center of the concavo-convex portion 15a-4 as a point of symmetry and has a rectangular shape. In addition, the number of irregularities of the concavo-convex portions 15a-1 to 15a-4 is larger than the number of irregularities of the concavo-convex portions 14a-1 to 14a-4.

Each of the concavo-convex portions 15a-1 to 15a-4 is mainly formed in a left lower portion of the pixel with respect to the pixel center t of each of the pixels 1005a-1 to 1005a-4, and thus it is possible to prevent the reflection of right oblique incident light and efficiently confine light to improve the quantum efficiency. In addition, the concavo-convex portions 15a-1 to 15a-4 are not formed to the light shielding film 5 between the pixels, and a flat portion is formed on a peripheral edge of each of the four pixels 1005a-1 to 1005a-4, and thus scattering may not occur due to the concavo-convex portion. In this case, there is no light leakage to the adjacent pixels, and thus color mixing can be prevented.

As illustrated in FIG. 5(b), four pixels 1005b-1 to 1005b-4 are formed in a clockwise order in the region 1005b corresponding to four pixels included in the solid-state imaging device 1003, and the light shielding film 5 is formed between the pixels (pixel boundary).

The region 1005b corresponding to four pixels is equivalent to the R5 region which is a right upper peripheral edge (the vicinity of a right upper vertex portion in the pixel region 1005-G) of the right upper peripheral portion in the pixel region 1005-G illustrated in FIG. 5(d).

The pixel 1005b-1 includes a concavo-convex portion 15b-1, and the concavo-convex portion 15b-1 has a point-symmetrical shape with the center of the concavo-convex portion 15b-1 as a point of symmetry and has a rectangular shape. The pixel 1005b-2 includes a concavo-convex portion 15b-2, and the concavo-convex portion 15b-2 has a point-symmetrical shape with the center of the concavo-convex portion 15b-2 as a point of symmetry and has a rectangular shape. The pixel 1005b-3 includes a concavo-convex portion 15b-3, and the concavo-convex portion 15b-3 has a point-symmetrical shape with the center of the concavo-convex portion 15b-3 as a point of symmetry and has a rectangular shape. The pixel 1005b-4 includes a concavo-convex portion 15b-4, and the concavo-convex portion 15b-4 has a point-symmetrical shape with the center of the concavo-convex portion 15b-4 as a point of symmetry and has a rectangular shape. In addition, a pitch (d5b) of each of the concavo-convex portions 15b-1 to 15b-4 is smaller than a pitch (d4b) of each of the concavo-convex portions 14b-1 to 14b-4, and the number of irregularities of each of the concavo-convex portions 15b-1 to 15b-4 is larger than the number of irregularities of each of the concavo-convex portions 14b-1 to 14b-4.

Each of the concavo-convex portions 15b-1 to 15b-4 is mainly formed in a left lower portion of the pixel with respect to the pixel center t of each of the pixels 1005b-1 to 1005b-4, and thus it is possible to prevent the reflection of right oblique incident light and efficiently confine light to improve the quantum efficiency. In addition, the concavo-convex portions 15b-1 to 15b-4 are not formed to the light shielding film 5 between the pixels, and a flat portion is formed on a peripheral edge of each of the four pixels 1005b-1 to 1005b-4, and thus scattering may not occur due to the concavo-convex portion. In this case, there is no light leakage to the adjacent pixels, and thus color mixing can be prevented.

As illustrated in FIG. 5(c), four pixels 1005c-1 to 1005c-4 are formed in a clockwise order in the region 1005c corresponding to four pixels included in the solid-state imaging device 1003, and the light shielding film 5 is formed between the pixels (pixel boundary).

The region 1005c corresponding to four pixels is equivalent to the R5 region which is a right upper peripheral edge (the vicinity of a right upper vertex portion in the pixel region 1005-G) of the right upper peripheral portion in the pixel region 1005-G illustrated in FIG. 5(d).

The pixel 1005c-1 includes a concavo-convex portion 15c-1, and the concavo-convex portion 15c-1 has a point-symmetrical shape with the center of the concavo-convex portion 15c-1 as a point of symmetry and has a polygonal shape. The pixel 1005c-2 includes a concavo-convex portion 15c-2, and the concavo-convex portion 15c-2 has a point-symmetrical shape with the center of the concavo-convex portion 15c-2 as a point of symmetry and has a polygonal shape. The pixel 1005c-3 includes a concavo-convex portion 15c-3, and the concavo-convex portion 15c-3 has a point-symmetrical shape with the center of the concavo-convex portion 15c-3 as a point of symmetry and has a polygonal shape. The pixel 1005c-4 includes a concavo-convex portion 15c-4, and the concavo-convex portion 15c-4 has a point-symmetrical shape with the center of the concavo-convex portion 15c-4 as a point of symmetry and has a polygonal shape. Note that each of the concavo-convex portions 15c-1 to 15c-4 has a point-symmetrical shape with the center of each of the concavo-convex portions as a point of symmetry, but may have an asymmetrical shape.

Each of the concavo-convex portions 15c-1 to 15c-4 is mainly formed in a left lower portion of the pixel with respect to the pixel center t of each of the pixels 1005c-1 to 1005c-4, and thus it is possible to prevent the reflection of right oblique incident light and efficiently confine light to improve the quantum efficiency. In addition, the concavo-convex portions 15c-1 to 15c-4 are not formed to the light shielding film 5 between the pixels, and a flat portion is formed on a peripheral edge of each of the four pixels 1005c-1 to 1005c-4, and thus scattering may not occur due to the concavo-convex portion. In this case, there is no light leakage to the adjacent pixels, and thus color mixing can be prevented. Since each of the concavo-convex portions 15c-1 to 15c-4 has a polygonal shape, the concavo-convex portion more efficiently covers a light converging region of right oblique incident light and efficiently confines light to improve a quantum effect, thereby further contributing to the uniformity of sensitivity in the chip (in the substrate).

As described above, the number of irregularities of the concavo-convex portion increases from the P3 region (the center portion of the pixel region) to the Q4 region and the R5 region, the number of pitches increases, and it is possible to achieve the uniformity of sensitivity in the chip (in the substrate) by changing a shape (changing a rectangular shape to a polygonal shape). That is, it is possible to improve contrast unevenness illustrated in FIG. 3(b), FIG. 4(d), and FIG. 5(d) by the solid-state imaging device according to the third embodiment (Example 3 of a solid-state imaging device) of the present technology.

The above-described contents of the solid-state imaging device according to the third embodiment (Example 3 of a solid-state imaging device) of the present technology can be applied to the above-described solid-state imaging devices according to the first and second embodiments of the present technology and solid-state imaging devices according to fourth to seventh embodiments of the present technology to be described later, unless there is no particular technical contradiction.

### 5. Fourth Embodiment (Example 4 of Solid-State Imaging Device)

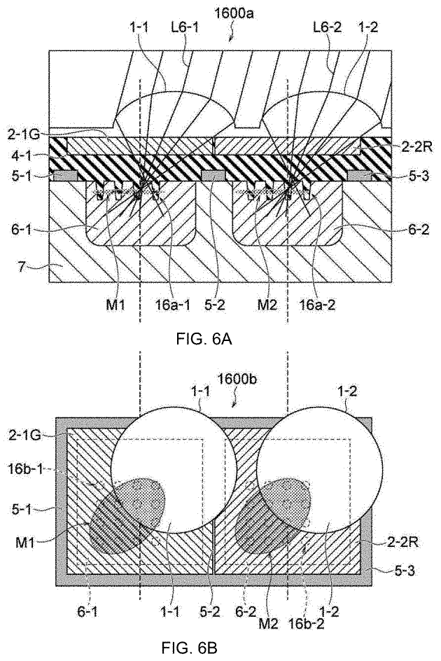

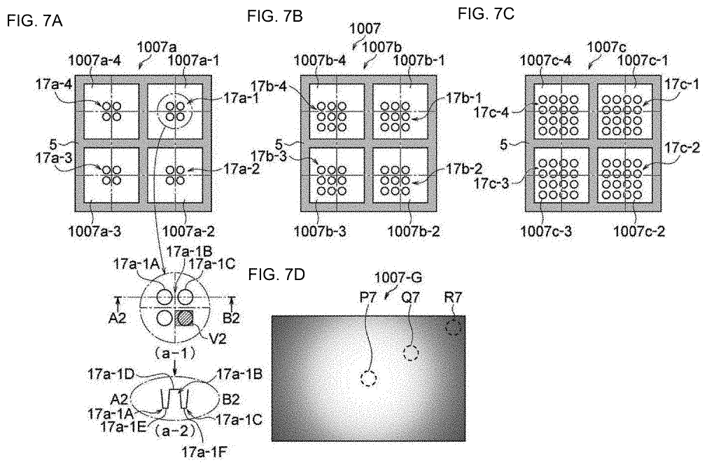

A solid-state imaging device according to a fourth embodiment (Example 4 of a solid-state imaging device) of the present technology will be described using FIGS. 6 and 7. FIG. 6 is a diagram illustrating a configuration example of the solid-state imaging device according to the fourth embodiment to which the present technology is applied. In more detail, FIG. 6(a) is a cross-sectional view of a solid-state imaging device 1600 (solid-state imaging device 1600a), and FIG. 6(b) is a planar layout diagram of the solid-state imaging device 1600 (solid-state imaging device 1600b). FIG. 7 is a diagram illustrating a configuration example of the solid-state imaging device according to the fourth embodiment to which the present technology is applied. In more detail, FIG. 7(a) is a plan view of a region 1007a corresponding to four pixels included in a solid-state imaging device 1007, FIG. 7(b) is a plan view of a region 1007b corresponding to four pixels included in the solid-state imaging device 1007, FIG. 7(c) is a plan view of a region 1007c corresponding to four pixels included in the solid-state imaging device 1007, and FIG. 7(d) is a diagram illustrating contrast unevenness in a pixel region 1007-G.

The solid-state imaging device 1600 (solid-state imaging devices 1600a and 1600b) includes on-chip lenses 1-1 and 1-2, color filters 2-1G and 2-2R, an insulating film 4, and photoelectric conversion units 6-1 and 6-2 formed in a semiconductor substrate 7 in order from a light incident side, and light converging regions M1 and M2 are formed by right oblique incident light L6-1 and L6-2 converged therein. Concavo-convex portions (a convex portion has a spindle shape) 16a-1 and 16a-2 are formed, and the reflection of light is prevented by the concavo-convex portions (a convex portion has a spindle shape) 16a-1 and 16a2. As illustrated in FIG. 6(b), concavo-convex portions (a convex portion has a spindle shape) 16b-1 and 16b-2 are formed to cover the light converging regions M1 and M2. The concavo-convex portions (a convex portion has a spindle shape) 16a-1 and 16a-2 can be manufactured by dry etching.

Next, description will be made using FIG. 7. As illustrated in FIG. 7(a), four pixels 1007a-1 to 1007a-4 are formed in a clockwise order in the region 1007a corresponding to four pixels included in the solid-state imaging device 1007, and the light shielding film 5 is formed between the pixels (pixel boundary).

The region 1007a corresponding to four pixels is equivalent to a P3 region which is a central portion in the pixel region 1007-G illustrated in FIG. 7(d).

The pixel 1007a-1 includes a concavo-convex portion 17a-1, and the concavo-convex portion 17a-1 has a point-symmetrical shape with a pixel center t of the pixel 1007a-1 as a point of symmetry and has a rectangular shape. The pixel 1007a-2 includes a concavo-convex portion 17a-2, and the concavo-convex portion 17a-2 has a point-symmetrical shape with a pixel center t of the pixel 1007a-2 as a point of symmetry and has a rectangular shape. The pixel 1007a-3 includes a concavo-convex portion 17a-3, and the concavo-convex portion 17a-3 has a point-symmetrical shape with a pixel center t of the pixel 1007a-3 as a point of symmetry and has a rectangular shape. The pixel 1007a-4 includes a concavo-convex portion 17a-4, and the concavo-convex portion 17a-4 has a point-symmetrical shape with a pixel center t of the pixel 1007a-4 as a point of symmetry and has a rectangular shape. Note that the pixel center t corresponds to the centers of each of the concavo-convex portions 17a-1 to 17a-4.

FIG. 7(a-1) is an enlarged plan view of the concavo-convex portion 17a-1 illustrated in FIG. 7(a), reference numerals 17a-1A and 17a-1C indicate a concave portion of the concavo-convex portion, and reference numeral 17a-1B indicates a convex portion of the concavo-convex portion. One pitch is a length from the center of the concave portion 17a-1A (the center of a lower side 17a-1E) to the center of the concave portion 17a-1C (the center of a lower side 17a-1F). In addition, a half pitch is a length from the center of the concave portion 17a-1A (the center of the lower side 17a-1E) or the center of the concave portion 17a-1C (the center of the lower side 17a-1F) to the center of the convex portion 17a-1B (the center of an upper side 17a-1D). Further, in the present specification, the range of an oblique line portion (a range indicated by reference numeral V2) in the concavo-convex portion 17a-1 is set to be one unit of the concavo-convex portion. Thus, the concavo-convex portion 17a-1 is constituted by four units. In addition, similarly, each of the concavo-convex portion 17a-2, the concavo-convex portion 17a-3, and the concavo-convex portion 17a-4 is four units. Each of a concavo-convex portion 17b-1, a concavo-convex portion 17b-2, a concavo-convex portion 17b-3, and a concavo-convex portion 17b-4 to be described below is nine units in FIG. 7(b), and each of a concavo-convex portion 17c-1, a concavo-convex portion 17c-2, a concavo-convex portion 17c-3, and a concavo-convex portion 17c-4 is 16 units in FIG. 7(c).

FIG. 7(a-2) is a cross-sectional view taken along line A2-B2 illustrated in FIG. 7(a-1). As illustrated in FIG. 7(a-2), a convex portion of the concavo-convex portion 17a-1 has a spindle shape and has an upper side when seen in a cross-sectional view. Note that the concavo-convex portion 17a-1 can be manufactured by dry etching.

The concavo-convex portions 17a-1 to 17a-4 are formed in the center portion (a region surrounding the pixel center t) of each of the pixels 1007a-1 to 1007a-4, and thus it is possible to efficiently confine vertically incident light to improve quantum efficiency. In addition, the concavo-convex portions 17a-1 to 17a-4 are not formed to the light shielding film 5 between the pixels, and a flat portion is formed on a peripheral edge of each of the four pixels 1007a-1 to 1007a-4. Thus, there is no light leakage to the adjacent pixels, and color mixing can be prevented.

As illustrated in FIG. 7(b), four pixels 1007b-1 to 1007b-4 are formed in a clockwise order in the region 1007b corresponding to four pixels included in the solid-state imaging device 1007, and the light shielding film 5 is formed between the pixels (pixel boundary).

The region 1007b corresponding to four pixels is equivalent to a Q7 region which is a right upper peripheral portion in the pixel region 1007-G illustrated in FIG. 7(d).

The pixel 1007b-1 includes a concavo-convex portion 17b-1, and the concavo-convex portion 17b-1 has a point-symmetrical shape with the center of the concavo-convex portion 17b-1 as a point of symmetry and has a rectangular shape. The pixel 1007b-2 includes a concavo-convex portion 17b-2, and the concavo-convex portion 17b-2 has a point-symmetrical shape with the center of the concavo-convex portion 17b-2 as a point of symmetry and has a rectangular shape. The pixel 1007b-3 includes a concavo-convex portion 17b-3, and the concavo-convex portion 17b-3 has a point-symmetrical shape with the center of the concavo-convex portion 17b-3 as a point of symmetry and has a rectangular shape. The pixel 1007b-4 includes a concavo-convex portion 17b-4, and the concavo-convex portion 17b-4 has a point-symmetrical shape with the center of the concavo-convex portion 17b-4 as a point of symmetry and has a rectangular shape. In addition, the number of irregularities of the concavo-convex portions 17b-1 to 17b-4 is larger than the number of irregularities of the concavo-convex portions 17a-1 to 17a-4. By increasing the number of irregularities of the concavo-convex portions 17b-1 to 17b-4, it is possible to increase sensitivity by more effectively preventing the reflection of right oblique light incident in the Q7 region.

Each of the concavo-convex portions 17b-1 to 17b-4 is mainly formed in a left lower portion of the pixel (a left upper portion of the pixel may also be used) with respect to the pixel center t of each of the pixels 1007b-1 to 1007b-4, and thus it is possible to prevent the reflection of right oblique incident light and efficiently confine light to improve the quantum efficiency. In a case where the concavo-convex portion is mainly formed in the right lower portion (or right upper portion) of the pixel, it is possible to prevent the reflection of left oblique incident light and efficiently confine light to improve quantum efficiency. In addition, the concavo-convex portions 17b-1 to 17b-4 are not formed to the light shielding film 5 between the pixels, and a flat portion is formed on a peripheral edge of each of the four pixels 1007b-1 to 1007b-4, and thus scattering may not occur due to the concavo-convex portion. In this case, there is no light leakage to the adjacent pixels, and thus color mixing can be prevented.

As illustrated in FIG. 7(c), four pixels 1007c-1 to 1007c-4 are formed in a clockwise order in the region 1007c corresponding to four pixels included in the solid-state imaging device 1007, and the light shielding film 5 is formed between the pixels (pixel boundary).

The region 1007c corresponding to four pixels is equivalent to an R7 region which is a right upper peripheral edge (the vicinity of a right upper vertex portion in the pixel region 1007-G) of the right upper peripheral portion in the pixel region 1007-G illustrated in FIG. 7(d).

The pixel 1007c-1 includes a concavo-convex portion 17c-1, and the concavo-convex portion 17c-1 has a point-symmetrical shape with the center of the concavo-convex portion 17c-1 as a point of symmetry and has a rectangular shape. The pixel 1007c-2 includes a concavo-convex portion 17c-2, and the concavo-convex portion 17c-2 has a point-symmetrical shape with the center of the concavo-convex portion 17c-2 as a point of symmetry and has a rectangular shape. The pixel 1007c-3 includes a concavo-convex portion 17c-3, and the concavo-convex portion 17c-3 has a point-symmetrical shape with the center of the concavo-convex portion 17c-3 as a point of symmetry and has a rectangular shape. The pixel 1007c-4 includes a concavo-convex portion 17c-4, and the concavo-convex portion 17c-4 has a point-symmetrical shape with the center of the concavo-convex portion 17c-4 as a point of symmetry and has a rectangular shape. In addition, the number of irregularities of the concavo-convex portions 17c-1 to 17c-4 is larger than the number of irregularities of the concavo-convex portions 17b-1 to 17b-4. By increasing the number of irregularities of the concavo-convex portions 17c-1 to 17c-4, it is possible to increase sensitivity by more effectively preventing the reflection of right oblique light incident in the R7 region.

Each of the concavo-convex portions 17c-1 to 17c-4 is mainly formed in a left lower portion of the pixel (a left upper portion of the pixel may also be used) with respect to the pixel center t of each of the pixels 1007c-1 to 1007c-4, and thus it is possible to prevent the reflection of right oblique incident light and efficiently confine light to improve the quantum efficiency. In a case where the concavo-convex portion is mainly formed in the right lower portion (or right upper portion) of the pixel, it is possible to prevent the reflection of left oblique incident light and efficiently confine light to improve quantum efficiency. In addition, the concavo-convex portions 17c-1 to 17c-4 are not formed to the light shielding film 5 between the pixels, and a flat portion is formed on a peripheral edge of each of the four pixels 1007c-1 to 1007c-4, and thus scattering may not occur due to the concavo-convex portion. In this case, there is no light leakage to the adjacent pixels, and thus color mixing can be prevented.

As described above, the number of irregularities of the concavo-convex portion increases from the P7 region (the center portion of the pixel region) to the Q7 region and the R7 region, and it is possible to achieve the uniformity of sensitivity in the chip (in the substrate). That is, it is possible to improve contrast unevenness illustrated in FIG. 7(d) by the solid-state imaging device according to the fourth embodiment (Example 4 of a solid-state imaging device) of the present technology.

The above-described contents of the solid-state imaging device according to the fourth embodiment (Example 4 of a solid-state imaging device) of the present technology can be applied to the above-described solid-state imaging device according to the first to third embodiments of the present technology and solid-state imaging devices according to fifth to seventh embodiments of the present technology to be described later, unless there is no particular technical contradiction.

### 6. Fifth Embodiment (Example 5 of Solid-State Imaging Device)

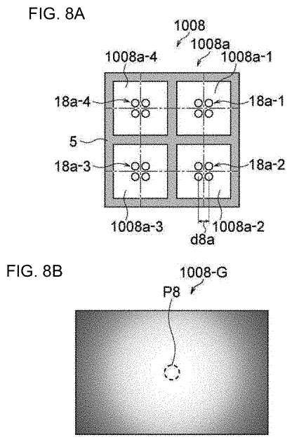

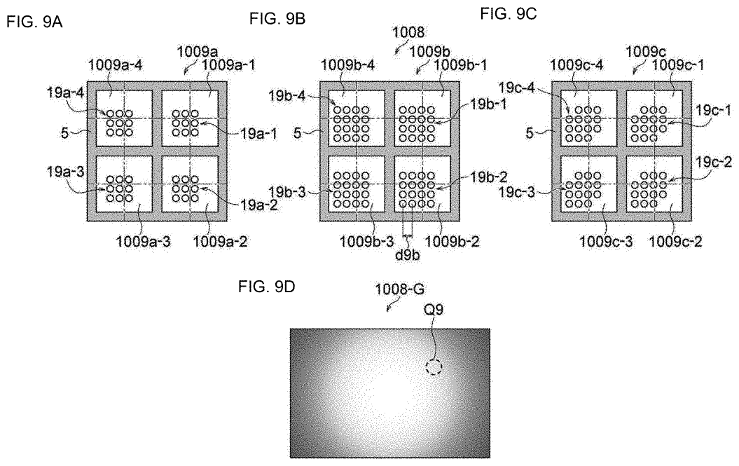

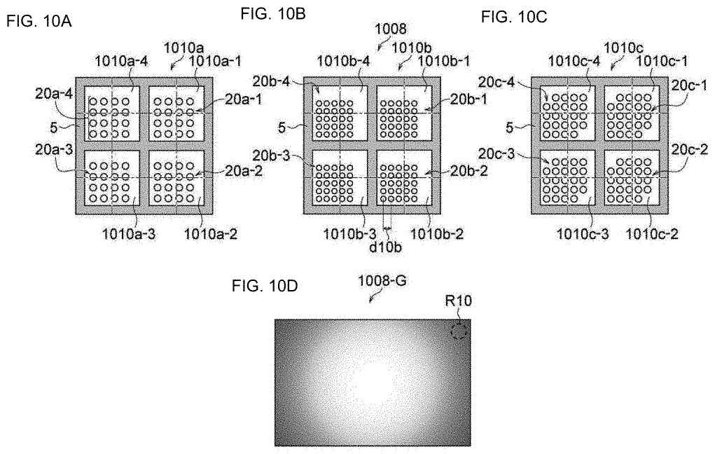

A solid-state imaging device according to a fifth embodiment (Example 5 of a solid-state imaging device) of the present technology will be described using FIGS. 8 to 10. FIG. 8 is a diagram illustrating a configuration example of the solid-state imaging device according to the fifth embodiment of the present technology. In more detail, FIG. 8(a) is a plan view of a region 1008a corresponding to four pixels included in a solid-state imaging device 1008, and FIG. 8(b) is a diagram illustrating contrast unevenness in a pixel region 1008-G. FIG. 9 is a diagram illustrating a configuration example of the solid-state imaging device according to the fifth embodiment of the present technology. In more detail, FIG. 9(a) is a plan view of a region 1009a corresponding to four pixels included in the solid-state imaging device 1008, FIG. 9(b) is a plan view of a region 1009b corresponding to four pixels included in the solid-state imaging device 1008, FIG. 9(c) is a plan view of a region 1009c corresponding to four pixels included in the solid-state imaging device 1008, and FIG. 9(d) is a diagram illustrating contrast unevenness in a pixel region 1008-G. FIG. 10 is a diagram illustrating a configuration example of the solid-state imaging device according to the fifth embodiment of the present technology. In more detail, FIG. 10(a) is a plan view of a region 1010a corresponding to four pixels included in the solid-state imaging device 1008, FIG. 10(b) is a plan view of a region 1010b corresponding to four pixels included in the solid-state imaging device 1008, FIG. 10(c) is a plan view of a region 1010c corresponding to four pixels included in the solid-state imaging device 1008, and FIG. 10(d) is a diagram illustrating contrast unevenness in the pixel region 1008-G.

As illustrated in FIG. 8, four pixels 1008a-1 to 1008a-4 are formed in a clockwise order in the region 1008a corresponding to four pixels included in the solid-state imaging device 1008, and a light shielding film 5 is formed between the pixels (pixel boundary).

The region 1008a corresponding to four pixels is equivalent to a P8 region which is a central portion in the pixel region 1008-G illustrated in FIG. 8(b).

The pixel 1008a-1 includes a concavo-convex portion 18a-1, and the concavo-convex portion 18a-1 has a point-symmetrical shape with a pixel center t of the pixel 1008a-1 as a point of symmetry and has a rectangular shape. The pixel 1008a-2 includes a concavo-convex portion 18a-2, and the concavo-convex portion 18a-2 has a point-symmetrical shape with a pixel center t of the pixel 1008a-2 as a point of symmetry and has a rectangular shape. The pixel 1008a-3 includes a concavo-convex portion 18a-3, and the concavo-convex portion 18a-3 has a point-symmetrical shape with a pixel center t of the pixel 1008a-3 as a point of symmetry and has a rectangular shape. The pixel 1008a-4 includes a concavo-convex portion 18a-4, and the concavo-convex portion 18a-4 has a point-symmetrical shape with a pixel center t of the pixel 1008a-4 as a point of symmetry and has a rectangular shape. Note that the pixel center t corresponds to the center of each of the concavo-convex portions 18a-1 to 18a-4.

The concavo-convex portions 18a-1 to 18a-4 are formed in the center portion (a region surrounding the pixel center t) of each of the pixels 1008a-1 to 1008a-4, and thus it is possible to efficiently confine vertically incident light to improve quantum efficiency. In addition, the concavo-convex portions 18a-1 to 18a-4 are not formed to the light shielding film 5 between the pixels, and a flat portion is formed on a peripheral edge of each of the four pixels 1008a-1 to 1008a-4. Thus, there is no light leakage to the adjacent pixels, and color mixing can be prevented.

As illustrated in FIG. 9(a), four pixels 1009a-1 to 1009a-4 are formed in a clockwise order in the region 1009a corresponding to four pixels included in the solid-state imaging device 1008, and the light shielding film 5 is formed between the pixels (pixel boundary).

The region 1009a corresponding to four pixels is equivalent to a Q9 region which is a right upper peripheral portion in the pixel region 1008-G illustrated in FIG. 9(d).

The pixel 1009a-1 includes a concavo-convex portion 19a-1, and the concavo-convex portion 19a-1 has a point-symmetrical shape with the center of the concavo-convex portion 19a-1 as a point of symmetry and has a rectangular shape. The pixel 1009a-2 includes a concavo-convex portion 19a-2, and the concavo-convex portion 19a-2 has a point-symmetrical shape with the center of the concavo-convex portion 19a-2 as a point of symmetry and has a rectangular shape. The pixel 1009a-3 includes a concavo-convex portion 19a-3, and the concavo-convex portion 19a-3 has a point-symmetrical shape with the center of the concavo-convex portion 19a-3 as a point of symmetry and has a rectangular shape. The pixel 1009a-4 includes a concavo-convex portion 19a-4, and the concavo-convex portion 19a-4 has a point-symmetrical shape with the center of the concavo-convex portion 19a-4 as a point of symmetry and has a rectangular shape. In addition, the number of irregularities of the concavo-convex portions 19a-1 to 19a-4 is larger than the number of irregularities of the concavo-convex portions 18a-1 to 18a-4.

Each of the concavo-convex portions 19a-1 to 19a-4 is mainly formed in a left lower portion of the pixel with respect to the pixel center t of each of the pixels 1009a-1 to 1009a-4, and thus it is possible to prevent the reflection of right oblique incident light and efficiently confine light to improve the quantum efficiency. In addition, the concavo-convex portions 19a-1 to 19a-4 are not formed to the light shielding film 5 between the pixels, and a flat portion is formed on a peripheral edge of each of the four pixels 1009a-1 to 1009a-4, and thus scattering may not occur due to the concavo-convex portion. In this case, there is no light leakage to the adjacent pixels, and thus color mixing can be prevented.

As illustrated in FIG. 9(b), four pixels 1009b-1 to 1009b-4 are formed in a clockwise order in the region 1009b corresponding to four pixels included in the solid-state imaging device 1008, and the light shielding film 5 is formed between the pixels (pixel boundary).

The region 1009b corresponding to four pixels is equivalent to the Q9 region which is a right upper peripheral portion in the pixel region 1008-G illustrated in FIG. 9(d).

The pixel 1009b-1 includes a concavo-convex portion 19b-1, and the concavo-convex portion 19b-1 has a point-symmetrical shape with the center of the concavo-convex portion 19b-1 as a point of symmetry and has a rectangular shape. The pixel 1009b-2 includes a concavo-convex portion 19b-2, and the concavo-convex portion 19b-2 has a point-symmetrical shape with the center of the concavo-convex portion 19b-2 as a point of symmetry and has a rectangular shape. The pixel 1009b-3 includes a concavo-convex portion 19b-3, and the concavo-convex portion 19b-3 has a point-symmetrical shape with the center of the concavo-convex portion 19b-3 as a point of symmetry and has a rectangular shape. The pixel 1009b-4 includes a concavo-convex portion 19b-4, and the concavo-convex portion 19b-4 has a point-symmetrical shape with the center of the concavo-convex portion 19b-4 as a point of symmetry and has a rectangular shape. In addition, a pitch (d9b) of each of the concavo-convex portions 19b-1 to 19b-4 is smaller than a pitch (d8a) of each of the concavo-convex portions 18a-1 to 18a-4, and the number of irregularities of each of the concavo-convex portions 19b-1 to 19b-4 is larger than the number of irregularities of each of the concavo-convex portions 18a-1 to 18a-4.

Each of the concavo-convex portions 19b-1 to 19b-4 is mainly formed in a left lower portion of the pixel with respect to the pixel center t of each of the pixels 1009b-1 to 1009b-4, and thus it is possible to prevent the reflection of right oblique incident light and efficiently confine light to improve the quantum efficiency. In addition, the concavo-convex portions 19b-1 to 19b-4 are not formed to the light shielding film 5 between the pixels, and a flat portion is formed on a peripheral edge of each of the four pixels 1009b-1 to 1009b-4, and thus scattering may not occur due to the concavo-convex portion. In this case, there is no light leakage to the adjacent pixels, and thus color mixing can be prevented.

As illustrated in FIG. 9(c), four pixels 1009c-1 to 1009c-4 are formed in a clockwise order in the region 1009c corresponding to four pixels included in the solid-state imaging device 1008, and the light shielding film 5 is formed between the pixels (pixel boundary).

The region 1009c corresponding to four pixels is equivalent to the Q9 region which is a right upper peripheral portion in the pixel region 1008-G G illustrated in FIG. 9(d).

The pixel 1009c-1 includes a concavo-convex portion 19c-1, and the concavo-convex portion 19c-1 has a point-symmetrical shape with the center of the concavo-convex portion 19c-1 as a point of symmetry and has a polygonal shape. The pixel 1009c-2 includes a concavo-convex portion 19c-2, and the concavo-convex portion 19c-2 has a point-symmetrical shape with the center of the concavo-convex portion 19c-2 as a point of symmetry and has a polygonal shape. The pixel 1009c-3 includes a concavo-convex portion 19c-3, and the concavo-convex portion 19c-3 has a point-symmetrical shape with the center of the concavo-convex portion 19c-3 as a point of symmetry and has a polygonal shape. The pixel 1009c-4 includes a concavo-convex portion 19c-4, and the concavo-convex portion 19c-4 has a point-symmetrical shape with the center of the concavo-convex portion 19c-4 as a point of symmetry and has a polygonal shape. Note that each of the concavo-convex portions 19c-1 to 19c-4 has a point-symmetrical shape with the center of each of the concavo-convex portions as a point of symmetry, but may have an asymmetrical shape.

Each of the concavo-convex portions 19c-1 to 19c-4 is mainly formed in a left lower portion of the pixel with respect to the pixel center t of each of the pixels 1009c-1 to 1009c-4, and thus it is possible to prevent the reflection of right oblique incident light and efficiently confine light to improve the quantum efficiency. In addition, the concavo-convex portions 19c-1 to 19c-4 are not formed to the light shielding film 5 between the pixels, and a flat portion is formed on a peripheral edge of each of the four pixels 1009c-1 to 1009c-4, and thus scattering may not occur due to the concavo-convex portion. In this case, there is no light leakage to the adjacent pixels, and thus color mixing can be prevented. Since each of the concavo-convex portions 19c-1 to 19c-4 has a polygonal shape, the concavo-convex portion more efficiently covers a light converging region of right oblique incident light and efficiently confines light to improve a quantum effect, thereby further contributing to the uniformity of sensitivity in the chip (in the substrate).

As illustrated in FIG. 10(a), four pixels 1010a-1 to 1010a-4 are formed in a clockwise order in the region 1010a corresponding to four pixels included in the solid-state imaging device 1008, and the light shielding film 5 is formed between the pixels (pixel boundary).

The region 1010a corresponding to four pixels is equivalent to an R10 region which is a right upper peripheral edge (the vicinity of a right upper vertex portion in the pixel region 1008-G) of the right upper peripheral portion in the pixel region 1008-G illustrated in FIG. 10(d).

The pixel 1010a-1 includes a concavo-convex portion 20a-1, and the concavo-convex portion 20a-1 has a point-symmetrical shape with the center of the concavo-convex portion 20a-1 as a point of symmetry and has a rectangular shape. The pixel 1010a-2 includes a concavo-convex portion 20a-2, and the concavo-convex portion 20a-2 has a point-symmetrical shape with the center of the concavo-convex portion 20a-2 as a point of symmetry and has a rectangular shape. The pixel 1010a-3 includes a concavo-convex portion 20a-3, and the concavo-convex portion 20a-3 has a point-symmetrical shape with the center of the concavo-convex portion 20a-3 as a point of symmetry and has a rectangular shape. The pixel 1010a-4 includes a concavo-convex portion 20a-4, and the concavo-convex portion 20a-4 has a point-symmetrical shape with the center of the concavo-convex portion 20a-4 as a point of symmetry and has a rectangular shape. In addition, the number of irregularities of the concavo-convex portions 20a-1 to 20a-4 is larger than the number of irregularities of the concavo-convex portions 19a-1 to 19a-4.

Each of the concavo-convex portions 20a-1 to 20a-4 is mainly formed in a left lower portion of the pixel with respect to the pixel center t of each of the pixels 1010a-1 to 1010a-4, and thus it is possible to prevent the reflection of right oblique incident light and efficiently confine light to improve the quantum efficiency. In addition, the concavo-convex portions 20a-1 to 20a-4 are not formed to the light shielding film 5 between the pixels, and a flat portion is formed on a peripheral edge of each of the four pixels 1010a-1 to 1010a-4, and thus scattering may not occur due to the concavo-convex portion. In this case, there is no light leakage to the adjacent pixels, and thus color mixing can be prevented.

As illustrated in FIG. 10(b), four pixels 1010b-1 to 1010b-4 are formed in a clockwise order in the region 1010b corresponding to four pixels included in the solid-state imaging device 1008, and the light shielding film 5 is formed between the pixels (pixel boundary).

The region 1010b corresponding to four pixels is equivalent to the R10 region which is a right upper peripheral edge (the vicinity of a right upper vertex portion in the pixel region 1008-G) of the right upper peripheral portion in the pixel region 1008-G illustrated in FIG. 10(d).

The pixel 1010b-1 includes a concavo-convex portion 20b-1, and the concavo-convex portion 20b-1 has a point-symmetrical shape with the center of the concavo-convex portion 20b-1 as a point of symmetry and has a rectangular shape. The pixel 1010b-2 includes a concavo-convex portion 20b-2, and the concavo-convex portion 20b-2 has a point-symmetrical shape with the center of the concavo-convex portion 20b-2 as a point of symmetry and has a rectangular shape. The pixel 1010b-3 includes a concavo-convex portion 20b-3, and the concavo-convex portion 20b-3 has a point-symmetrical shape with the center of the concavo-convex portion 20b-3 as a point of symmetry and has a rectangular shape. The pixel 1010b-4 includes a concavo-convex portion 20b-4, and the concavo-convex portion 20b-4 has a point-symmetrical shape with the center of the concavo-convex portion 20b-4 as a point of symmetry and has a rectangular shape. In addition, a pitch (d10b) of each of the concavo-convex portions 20b-1 to 20b-4 is smaller than a pitch (d9b) of each of the concavo-convex portions 19b-1 to 19b-4, and the number of irregularities of each of the concavo-convex portions 20b-1 to 20b-4 is larger than the number of irregularities of each of the concavo-convex portions 19b-1 to 19b-4.

Each of the concavo-convex portions 20b-1 to 20b-4 is mainly formed in a left lower portion of the pixel with respect to the pixel center t of each of the pixels 1010b-1 to 1010b-4, and thus it is possible to prevent the reflection of right oblique incident light and efficiently confine light to improve the quantum efficiency. In addition, the concavo-convex portions 20b-1 to 20b-4 are not formed to the light shielding film 5 between the pixels, and a flat portion is formed on a peripheral edge of each of the four pixels 1010b-1 to 1010b-4, and thus scattering may not occur due to the concavo-convex portion. In this case, there is no light leakage to the adjacent pixels, and thus color mixing can be prevented.

As illustrated in FIG. 10(c), four pixels 1010c-1 to 1010c-4 are formed in a clockwise order in the region 1010c corresponding to four pixels included in the solid-state imaging device 1008, and the light shielding film 5 is formed between the pixels (pixel boundary).

The region 1010c corresponding to four pixels is equivalent to the R10 region which is a right upper peripheral edge (the vicinity of a right upper vertex portion in the pixel region 1008-G) of the right upper peripheral portion in the pixel region 1008-G illustrated in FIG. 10(d).

The pixel 1010c-1 includes a concavo-convex portion 20c-1, and the concavo-convex portion 20c-1 has a point-symmetrical shape with the center of the concavo-convex portion 20c-1 as a point of symmetry and has a polygonal shape. The pixel 1010c-2 includes a concavo-convex portion 20c-2, and the concavo-convex portion 20c-2 has a point-symmetrical shape with the center of the concavo-convex portion 20c-2 as a point of symmetry and has a polygonal shape. The pixel 1010c-3 includes a concavo-convex portion 20c-3, and the concavo-convex portion 20c-3 has a point-symmetrical shape with the center of the concavo-convex portion 20c-3 as a point of symmetry and has a polygonal shape. The pixel 1010c-4 includes a concavo-convex portion 20c-4, and the concavo-convex portion 20c-4 has a point-symmetrical shape with the center of the concavo-convex portion 20c-4 as a point of symmetry and has a polygonal shape. Note that each of the concavo-convex portions 20c-1 to 20c-4 has a point-symmetrical shape with the center of each of the concavo-convex portions as a point of symmetry, but may have an asymmetrical shape.

Each of the concavo-convex portions 20c-1 to 20c-4 is mainly formed in a left lower portion of the pixel with respect to the pixel center t of each of the pixels 1010c-1 to 1010c-4, and thus it is possible to prevent the reflection of right oblique incident light and efficiently confine light to improve the quantum efficiency. In addition, the concavo-convex portions 20c-1 to 20c-4 are not formed to the light shielding film 5 between the pixels, and a flat portion is formed on a peripheral edge of each of the four pixels 1010c-1 to 1010c-4, and thus scattering may not occur due to the concavo-convex portion. In this case, there is no light leakage to the adjacent pixels, and thus color mixing can be prevented. Since each of the concavo-convex portions 20c-1 to 20c-4 has a polygonal shape, the concavo-convex portion more efficiently covers a light converging region of right oblique incident light and efficiently confines light to improve a quantum effect, thereby further contributing to the uniformity of sensitivity in the chip (in the substrate).

As described above, the number of irregularities of the concavo-convex portion increases from the P8 region (the center portion of the pixel region) to the Q9 region and the R10 region, the number of pitches increases, and it is possible to achieve the uniformity of sensitivity in the chip (in the substrate) by changing a shape (changing a rectangular shape to a polygonal shape). That is, it is possible to improve contrast unevenness illustrated in FIG. 8(b), FIG. 9(d), and FIG. 10(d) by the solid-state imaging device according to the fifth embodiment (Example 5 of a solid-state imaging device) of the present technology.

The above-described contents of the solid-state imaging device according to the fifth embodiment (Example 5 of a solid-state imaging device) of the present technology can be applied to the above-described solid-state imaging devices according to the first to fourth embodiments of the present technology and solid-state imaging devices according to sixth and seventh embodiments of the present technology to be described later, unless there is no particular technical contradiction.

### 7. Sixth Embodiment (Example 6 of Solid-State Imaging Device)

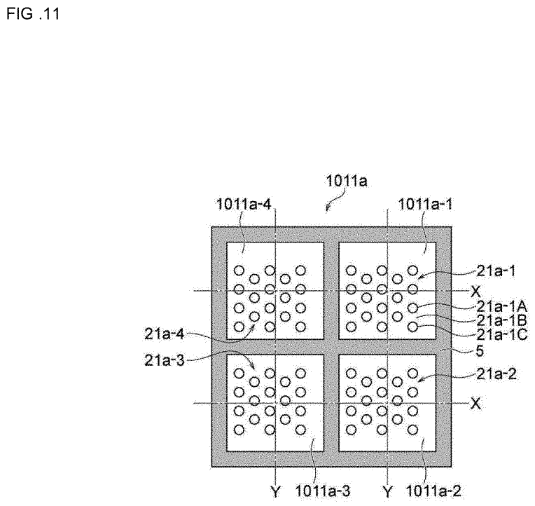

A solid-state imaging device according to a sixth embodiment (Example 6 of a solid-state imaging device) of the present technology will be described using FIG. 11. FIG. 11 is a diagram illustrating a configuration example of four pixels included in the solid-state imaging device according to the sixth embodiment to which the present technology is applied, and more specifically, is a plan view of a region 1011a corresponding to four pixels included in the solid-state imaging device according to the sixth embodiment.

As illustrated in FIG. 11, four pixels 1011a-1 to 1011a-4 are formed in a clockwise order in the region 1011a corresponding to four pixels, and the light shielding film 5 is formed between the pixels (pixel boundary).

The pixel 1011a-1 includes a concavo-convex portion 21a-1, the pixel 1011a-2 includes a concavo-convex portion 21a-2, the pixel 1011a-3 includes a concavo-convex portion 21a-3, and the pixel 1011a-4 includes a concavo-convex portion 21a-4.

As illustrated in FIG. 11, a pitch of the concavo-convex portion 21a-2 is deviated by a half pitch in a Y-axis direction (upward in FIG. 11) with respect to the concavo-convex portion 21a-1. Note that, in order to efficiently confine light and improve a quantum effect in accordance with the incidence direction of incident light (to appropriately deal with a focal region), a deviation width may be set arbitrarily, and examples of the deviation width includes one pitch, a quarter pitch, and the like. Here, a length from the center of a concave portion 21a-1A to the center of a concave portion 21a-C is set to be one pitch, and a length from the center of the concave portion 21a-1A or the concave portion 21a-1C to the center of a convex portion 21a-1B is set to be a half pitch.

As illustrated in FIG. 11, the pitch of the concavo-convex portion 21a-3 is deviated by a half pitch in the Y-axis direction (upward in FIG. 11) with respect to the concavo-convex portion 21a-4. Note that, in order to efficiently confine light and improve a quantum effect in accordance with the incidence direction of incident light (to appropriately deal with a focal region), a deviation width may be set arbitrarily, and examples of the deviation width includes one pitch, a quarter pitch, and the like. Here, one pitch and a half pitch are defined as described above.

The above-described contents of the solid-state imaging device according to the sixth embodiment (Example 6 of a solid-state imaging device) of the present technology can be applied to the above-described solid-state imaging devices according to the first to fifth embodiments of the present technology and a solid-state imaging device according to a seventh embodiment of the present technology to be described later, unless there is no particular technical contradiction.

### 8. Seventh Embodiment (Example 7 of Solid-State Imaging Device)

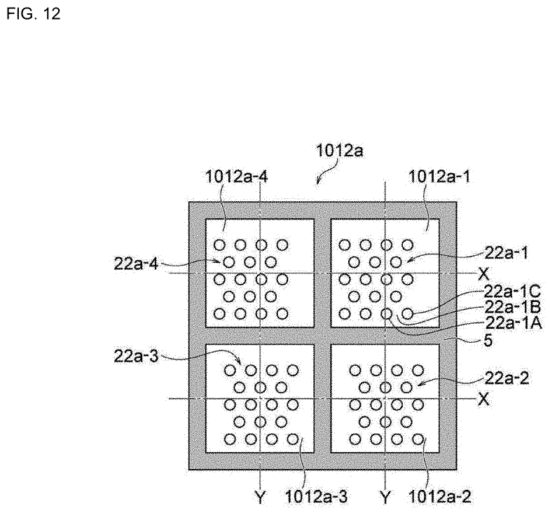

A solid-state imaging device according to a seventh embodiment (Example 7 of a solid-state imaging device) of the present technology will be described using FIG. 12. FIG. 12 is a diagram illustrating a configuration example of four pixels included in the solid-state imaging device according to the seventh embodiment to which the present technology is applied, and more specifically, is a plan view of a region 1012a corresponding to four pixels included in the solid-state imaging device according to the seventh embodiment.

As illustrated in FIG. 12, four pixels 1012a-1 to 1012a-4 are formed in a clockwise order in the region 1012a corresponding to four pixels, and the light shielding film 5 is formed between the pixels (pixel boundary).

The pixel 1012a-1 includes a concavo-convex portion 22a-1, the pixel 1012a-2 includes a concavo-convex portion 22a-2, the pixel 1012a-3 includes a concavo-convex portion 22a-3, and the pixel 1012a-4 includes a concavo-convex portion 22a-4.

As illustrated in FIG. 12, a pitch of the concavo-convex portion 22a-2 is deviated by a half pitch in an X-axis direction (rightward in FIG. 11) with respect to the concavo-convex portion 22a-1. Note that, in order to efficiently confine light and improve a quantum effect in accordance with the incidence direction of incident light (to appropriately deal with a focal region), a deviation width may be set arbitrarily, and examples of the deviation width includes one pitch, a quarter pitch, and the like. Here, a length from the center of a concave portion 22a-1A to the center of a concave portion 22a-C is set to be one pitch, and a length from the center of the concave portion 22a-1A or the concave portion 22a-1C to the center of a convex portion 22a-1B is set to be a half pitch.

As illustrated in FIG. 12, a pitch of the concavo-convex portion 22a-3 is deviated by a half pitch in the X-axis direction (rightward in FIG. 12) with respect to the concavo-convex portion 22a-4. Note that, in order to efficiently confine light and improve a quantum effect in accordance with the incidence direction of incident light (to appropriately deal with a focal region), a deviation width may be set arbitrarily, and examples of the deviation width includes one pitch, a quarter pitch, and the like. Here, one pitch and a half pitch are defined as described above.

The above-described contents of the solid-state imaging device according to the seventh embodiment (Example 7 of a solid-state imaging device) of the present technology can be applied to the above-described solid-state imaging devices according to the first to sixth embodiments of the present technology, unless there is no particular technical contradiction.

### 9. Eighth Embodiment (Example of Electronic Equipment)

Electronic equipment according to an eighth embodiment of the present technology is electronic equipment on which the solid-state imaging device among the solid-state imaging devices according to any one of the first to seventh embodiments of the present technology is mounted.

### 10. Example of Use of Solid-State Imaging Device to which the Present Technology is Applied

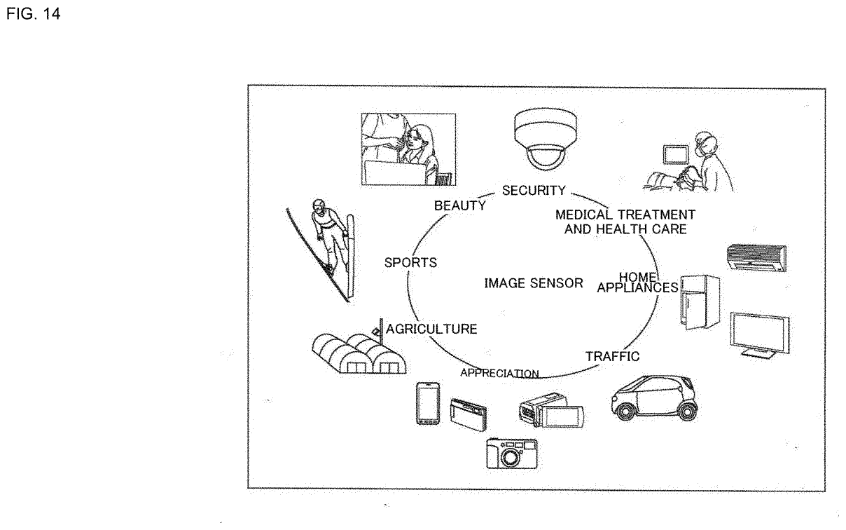

FIG. 14 is a diagram illustrating an example in which the solid-state imaging devices according to the first to seventh embodiments of the present technology are used as an image sensor (solid-state imaging device).

The above-described solid-state imaging devices according to the first to seventh embodiments can be used in various cases where light such as visible light, infrared light, ultraviolet light, and X rays is sensed as follows. That is, as illustrated in FIG. 14, the solid-state imaging device according to any one of the first to seventh embodiments can be used in devices (for example, the electronic equipment according to the eighth embodiment described above) which are used in, for example, a field of appreciation in which an image provided for appreciation is captured, a field of traffic, a field of home appliances, a field of medical treatment and health care, a field of security, a field of beauty, a field of sports, and a field of agriculture.

Specifically, in a field of appreciation, the solid-state imaging device according to any one of the first to seventh embodiments can be used in devices for capturing an image provided for appreciation, such as a digital camera, a smartphone, and a mobile phone with a camera function.

In a field of traffic, the solid-state imaging device according to any one of the first to seventh embodiments can be used in devices provided for traffic, such as an in-vehicle sensor that images the front, rear, surroundings, inside, and the like of a vehicle, a monitoring camera that monitors traveling vehicles and roads, and a distance measuring sensor that measures a distance between vehicles, and the like for safe driving such as automatic stop, recognition of a driver's conditions, and the like.

In a field of home appliances, the solid-state imaging device according to any one of the first to seventh embodiments can be used in devices provided for home appliances, such as a television receiver, a refrigerator, and an air conditioner, for example, in order to image a user's gesture and operate equipment in response to the gesture.

In a field of medical treatment and health care, the solid-state imaging device according to any one of the first to seventh embodiments can be used in devices provided for medical treatment and health care, such as an endoscope and a device that performs angiography by receiving infrared light.

In a field of security, the solid-state imaging device according to any one of the first to seventh embodiments can be used in devices provided for security, such as a surveillance camera for crime prevention and a camera for person authentication.

In a field of beauty, the solid-state imaging device according to any one of the first to seventh embodiments can be used in devices provided for beauty such as a skin measuring instrument that images the skin and a microscope that images the scalp.

In a field of sports, the solid-state imaging device according to any one of the first to seventh embodiments can be used in devices provided for sports, such as an action camera and a wearable camera for sports applications.

In a field of agriculture, the solid-state imaging device according to any one of the first to seventh embodiments can be used in devices provided for agriculture, such as a camera that monitors the conditions of fields and crops.

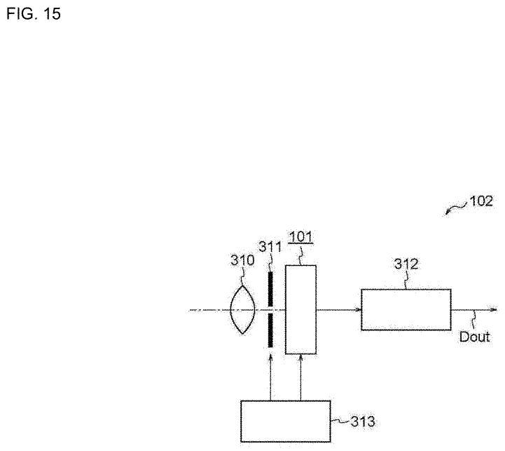

Next, an example in which the solid-state imaging devices according to the first to seventh embodiments of the present technology are used will be specifically described. For example, the solid-state imaging device according to any one of the first to seventh embodiments described above is used. Specifically, a solid-state imaging device 101 can be applied to any type of electronic equipment equipped with an imaging function, for example, a camera system such as a digital still camera or a video camera, and a mobile phone having an imaging function. As an example, a schematic configuration of electronic equipment 102 (camera) is illustrated in FIG. 15. The electronic equipment 102 is a video camera that can capture a still image or a moving image, and includes the solid-state imaging device 101, an optical system (optical lens) 310, a shutter device 311, a driving portion 313 that drives the solid-state imaging device 101 and the shutter device 311, and a signal processing unit 312.

The optical system 310 guides image light (incident light) from a subject to a pixel portion 101a of the solid-state imaging device 101. The optical system 310 may be constituted by a plurality of optical lenses. The shutter device 311 controls a light irradiation period and a light shielding period for the solid-state imaging device 101. The driving portion 313 controls a transfer operation of the solid-state imaging device 101 and a shutter operation of the shutter device 311. The signal processing unit 312 performs various signal processing on signals output from the solid-state imaging device 101. A video signal Dout after signal processing is stored in a storage medium such as a memory or is output to a monitor or the like.

### 11. Example of Application to Endoscopic Surgery System

The present technology can be applied to various products. For example, the technology according to the present disclosure (the present technology) may be applied to an endoscopic surgery system.

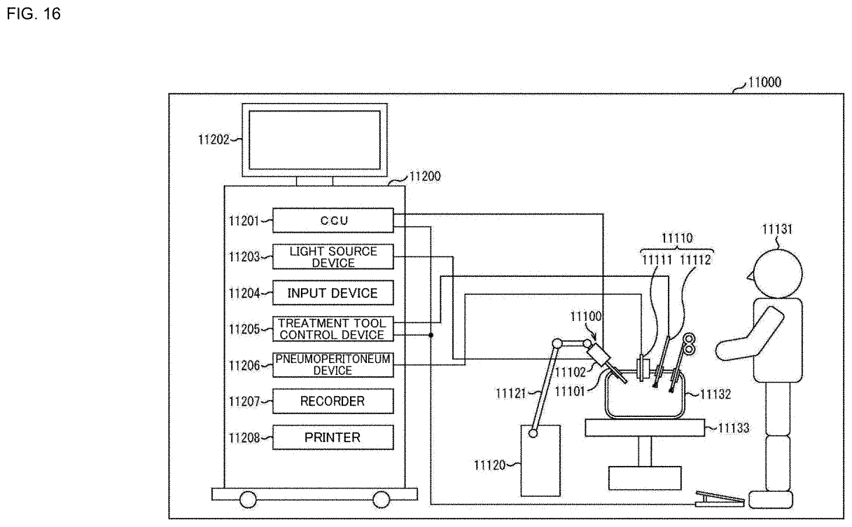

FIG. 16 is a diagram illustrating an example of a schematic configuration of an endoscopic surgery system to which the technology according to the present disclosure (the present technology) can be applied.

FIG. 16 shows a state where a surgeon (doctor) 11131 is performing a surgical operation on a patient 11132 on a patient bed 11133 by using the endoscopic surgery system 11000. As illustrated in the drawing, the endoscopic surgery system 11000 is constituted by an endoscope 11100, another surgical tool 11110 such as a pneumoperitoneum tube 11111 or an energy treatment tool 11112, a support arm device 11120 that supports the endoscope 11100, and a cart 11200 in which various devices for endoscopic surgery are mounted.

The endoscope 11100 includes a lens barrel 11101 of which a region having a predetermined length from a distal end is inserted into a body cavity of the patient 11132, and a camera head 11102 connected to a base end of the lens barrel 11101. In the example illustrated in the drawing, the endoscope 11100 configured as a so-called rigid endoscope having the rigid lens barrel 11101 is illustrated, but the endoscope 11100 may be configured as a so-called soft endoscope having a soft lens barrel.

An opening in which an objective lens is fitted is provided at a distal end of the lens barrel 11101. A light source device 11203 is connected to the endoscope 11100, and light generated by the light source device 11203 is guided to the tip of the lens barrel by the light guide extending into the lens barrel 11101, and is emitted to an observation target in the body cavity of the patient 11132 via the objective lens. Here, the endoscope 11100 may be a direct endoscope or may be a perspective endoscope or a side endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is constituted by a central processing unit (CPU), a graphics processing unit (GPU), or the like, and generally controls operations of the endoscope 11100 and the display device 11202. In addition, the CCU 11201 receives an image signal from the camera head 11102, and performs various types of image processing for displaying an image based on the image signal, for example, development processing (demosaic processing) on the image signal.

The display device 11202 displays an image based on the image signal subjected to the image processing by the CCU 11201 under the control of the CCU 11201.

The light source device 11203 is constituted by a light source such as a light emitting diode (LED), and supplies the endoscope 11100 with irradiation light for imaging a surgical part or the like.

An input device 11204 is an input interface for the endoscopic surgery system 11000. A user can input various types of information and input an instruction to the endoscopic surgery system 11000 via the input device 11204. For example, the user inputs an instruction to change imaging conditions (the type of irradiation light, a magnification, a focal distance, and the like) and the like by the endoscope 11100.

A treatment tool control device 11205 controls the driving of an energy treatment tool 11112 for cauterizing or incising tissue, sealing a blood vessel, or the like. In order to secure a field of view of the endoscope 11100 and secure an operation space of the surgeon, a pneumoperitoneum device 11206 sends gas into the body cavity of the patient 11132 via the pneumoperitoneum tube 11111 in order to inflate the body cavity. A recorder 11207 is a device that can record various types of information related to surgery. A printer 11208 is a device that can print various types of information related to surgery in various formats such as text, images and graphs.

Note that the light source device 11203 that supplies irradiation light for imaging a surgical part to the endoscope 11100 can be constituted by, for example, an LED, a laser light source, or a white light source constituted by a combination thereof. In a case where a white light source is constituted by a combination of RGB laser light sources, the output intensity of each color (each wavelength) and an output timing can be controlled with high accuracy, and thus white balance of a captured image can be adjusted in the light source device 11203. Further, in this case, an observation target is irradiated with laser beams from the RGB laser light sources in a time-division manner, and the driving of the imaging element of the camera head 11102 is controlled in synchronization with the irradiation timing, whereby it is also possible to capture images corresponding to RGB in a time-division manner. According to the method, a color image can be obtained without providing a color filter in the imaging element.

Further, the driving of the light source device 11203 may be controlled to change the intensity of output light at predetermined time intervals. The driving of the imaging element of the camera head 11102 is controlled in synchronization with the timing of the change in the light intensity to acquire an image in a time-division manner, and the image is synthesized, whereby it is possible to generate a so-called image in a high dynamic range without underexposure or overexposure.

Further, the light source device 11203 may be configured to be able to supply light having a predetermined wavelength band corresponding to special light observation. In the special light observation, for example, by emitting light in a band narrower than that of irradiation light (that is, white light) during normal observation using wavelength dependence of light absorption in a body tissue, so-called narrow band light observation (narrow band imaging) in which a predetermined tissue such as a blood vessel in the mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue, and observing fluorescence from the body tissue (autofluorescence observation), or locally injecting a reagent such as indocyanine green (ICG) to a body tissue, and emitting excitation light corresponding to a fluorescence wavelength of the reagent to the body tissue to obtain a fluorescence image. The light source device 11203 can supply narrow band light and/or excitation light corresponding to such special light observation.

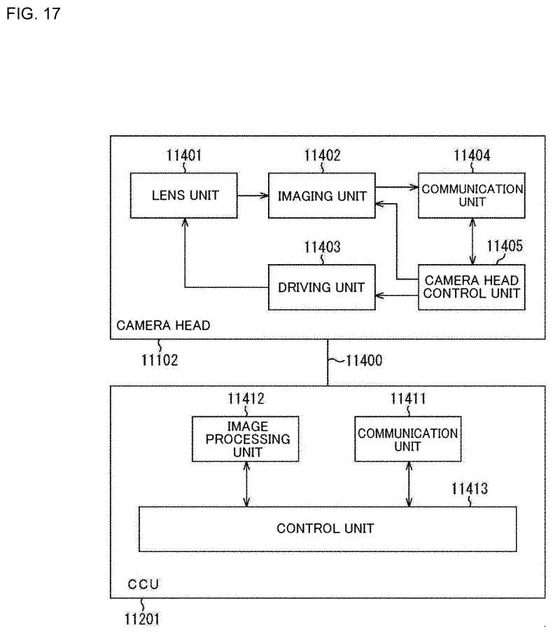

FIG. 17 is a block diagram illustrating an example of functional configurations of the camera head 11102 and the CCU 11201 illustrated in FIG. 16.

The camera head 11102 includes a lens unit 11401, an imaging unit 11402, a driving unit 11403, a communication unit 11404, and a camera head control unit 11405. The CCU 11201 includes a communication unit 11411, an image processing unit 11412, and a control unit 11413. The camera head 11102 and the CCU 11201 are connected to each other via a transmission cable 11400 so that they can communicate with each other.

The lens unit 11401 is an optical system provided at a portion for connection to the lens barrel 11101. Observation light taken from the tip of the lens barrel 11101 is guided to the camera head 11102 and is incident on the lens unit 11401. The lens unit 11401 is constituted by a combination of a plurality of lenses including a zoom lens and a focus lens.

The imaging unit 11402 is constituted by an imaging element. The imaging element constituting the imaging unit 11402 may be one element (so-called single plate type) or a plurality of elements (so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the surgeon 11131 can ascertain the depth of biological tissues in the surgical part more accurately. Here, when the imaging unit 11402 is configured as a multi-plate type, a plurality of lens units 11401 may be provided according to the imaging elements.

Further, the imaging unit 11402 may not be necessarily provided in the camera head 11102. For example, the imaging unit 11402 may be provided inside the lens barrel 11101, immediately after the objective lens.

The driving unit 11403 is constituted by an actuator, and moves the zoom lens and the focus lens of the lens unit 11401 by a predetermined distance along an optical axis under the control of the camera head control unit 11405. Thereby, the magnification and the focus of the image captured by the imaging unit 11402 can be appropriately adjusted.

The communication unit 11404 is constituted by a communication device for transmitting or receiving various pieces of information to or from the CCU 11201. The communication unit 11404 transmits the image signal obtained from the imaging unit 11402 as RAW data to the CCU 11201 via the transmission cable 11400.

The communication unit 11404 also receives a control signal for controlling the driving of the camera head 11102 from the CCU 11201 and supplies the control signal to the camera head control unit 11405. The control signal includes information related to imaging conditions, for example, information specifying a frame rate of a captured image, information specifying an exposure value during imaging, and/or information specifying a magnification and a focus of a captured image.

Note that the imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, an auto focus (AF) function, and an auto white balance (AWB) function are provided in the endoscope 11100.

The camera head control unit 11405 controls the driving of the camera head 11102 on the basis of the control signal from the CCU 11201 received via the communication unit 11404.

The communication unit 11411 is constituted by a communication device for transmitting and receiving various pieces of information to and from the camera head 11102. The communication unit 11411 receives the image signal transmitted from the camera head 11102 via the transmission cable 11400.

In addition, the communication unit 11411 transmits a control signal for controlling the driving of the camera head 11102 to the camera head 11102. The image signal and the control signal can be transmitted through telecommunication, optical communication or the like.

The image processing unit 11412 performs various image processing on the image signal which is the RAW data transmitted from the camera head 11102.

The control unit 11413 performs various controls regarding imaging of the surgical part or the like using the endoscope 11100 and the display of a captured image obtained by imaging the surgical part or the like. For example, the control unit 11413 generates a control signal for controlling the driving of the camera head 11102.

Further, the control unit 11413 causes the display device 11202 to display the captured image obtained by imaging the surgical part or the like on the basis of the image signal subjected to image processing by the image processing unit 11412. In this case, the control unit 11413 may recognize various objects in the captured image using various image recognition technologies. For example, the control unit 11413 can recognize surgical tools such as forceps, specific biological parts, bleeding, mist when the energy treatment tool 11112 is used, and the like by detecting the edge shape, color, and the like of the object included in the captured image. When the control unit 11413 causes the display device 11202 to display the captured image, it may cause various types of surgical support information to be superimposed and displayed with the image of the surgical part using the recognition result. When the surgical support information is displayed in an overlapping manner and is presented to the surgeon 11131, it is possible to reduce the burden on the surgeon 11131, and the surgeon 11131 can reliably proceed with the surgery.

The transmission cable 11400 that connects the camera head 11102 to the CCU 11201 is an electrical signal cable compatible with communication of an electrical signal, an optical fiber compatible with optical communication, or a composite cable thereof.

Here, in the example illustrated in the drawing, wired communication is performed using the transmission cable 11400, but the communication between the camera head 11102 and the CCU 11201 may be performed wirelessly.

The example of the endoscopic surgery system to which the technology according to the present disclosure can be applied has been described above. The technology according to the present disclosure can be applied to the endoscope 11100, (the imaging unit 11402 of) the camera head 11102, or the like among the configurations described above. Specifically, the solid-state imaging device according to the present technology can be applied to the imaging unit 10402. By applying the technology according to the present disclosure to the endoscope 11100, (the imaging unit 11402 of) the camera head 11102, or the like, it is possible to improve the performance of the endoscope 11100, (the imaging unit 11402 of) the camera head 11102, or the like.

While the endoscopic surgery system has been described here as an example, the technology according to the present disclosure may be applied to other systems, for example, a microscopic surgery system.

### 12. Example of Application to Moving Body

The technology according to the present disclosure (the present technology) can be applied to various products. For example, the technology of the present disclosure may be implemented as a device mounted in any type of moving body such as an automobile, an electric automobile, a motorbike, a hybrid electric automobile, a bicycle, a personal mobility, an airplane, a drone, a ship, and a robot.

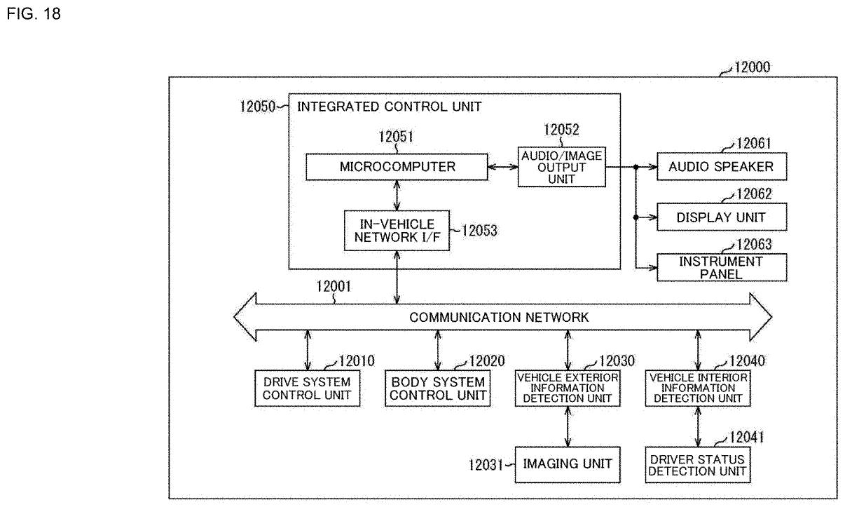

FIG. 18 is a block diagram showing a schematic configuration example of a vehicle control system that is an example of a moving body control system to which the technology according to the present disclosure can be applied.

A vehicle control system 12000 includes a plurality of electronic control units connected to each other through a communication network 12001. In an example illustrated in FIG. 18, the vehicle control system 12000 includes a drive system control unit 12010, a body system control unit 12020, a vehicle exterior information detection unit 12030, a vehicle interior information detection unit 12040, and an integrated control unit 12050. In addition, as the functional configuration of the integrated control unit 12050, a microcomputer 12051, an audio/image output unit 12052, and an in-vehicle network interface (I/F) 12053 are illustrated in the drawing.

The drive system control unit 12010 controls operations of devices related to a drive system of a vehicle according to various programs. For example, the drive system control unit 12010 functions as a control device for a driving force generating device for generating a driving force of a vehicle such as an internal combustion engine or a drive motor, a driving force transmission mechanism for transmitting a driving force to wheels, a steering mechanism for adjusting a steering angle of a vehicle, and a braking device for generating a braking force of a vehicle.

The body system control unit 12020 controls operations of various devices mounted in the vehicle body according to various programs. For example, the body system control unit 12020 functions as a control device such as a keyless entry system, a smart key system, a power window device, or various lamps such as a headlamp, a back lamp, a brake lamp, a turn signal and a fog lamp. In this case, radio waves transmitted from a portable device that substitutes for a key or signals of various switches may be input to the body system control unit 12020. The body system control unit 12020 receives inputs of the radio waves or signals, and controls a door lock device, a power window device, and a lamp of the vehicle.

The vehicle exterior information detection unit 12030 detects information outside the vehicle in which the vehicle control system 12000 is mounted. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road based on the received image.

The imaging unit 12031 is an optical sensor that receives light and outputs an electrical signal according to the intensity of the light received. The imaging unit 12031 can output an electrical signal as an image or output it as a distance measurement information. The light received by the imaging unit 12031 may be visible light or invisible light such as infrared light.

The vehicle interior information detection unit 12040 detects information on the interior of the vehicle. In the vehicle interior information detection unit 12040, for example, a driver status detection unit 12041 that detects the recognition of a driver's conditions is connected. The driver status detection unit 12041 includes, for example, a camera that images the driver, and the vehicle interior information detection unit 12040 may calculate the degree of fatigue or degree of concentration of the driver based on detection information input from the driver status detection unit 12041, and may determine whether the driver is asleep.

The microcomputer 12051 can calculate a control target value of the driving force generation device, the steering mechanism, or the braking device on the basis of the information inside and outside the vehicle acquired by the vehicle exterior information detection unit 12030 or the vehicle interior information detection unit 12040, and output a control command to the drive system control unit 12010. For example, the microcomputer 12051 can perform coordinated control for realizing an advanced driver assistance system (ADAS) function including vehicle collision avoidance, shock alleviation, following travel based on an inter-vehicle distance, vehicle speed maintenance travel, a vehicle collision warning, or a vehicle lane deviation warning.

Further, the microcomputer 12051 can perform coordinated control for the purpose of automated driving or the like in which autonomous travel is performed without depending on an operation of a driver by controlling the driving force generator, the steering mechanism, the braking device, and the like on the basis of information regarding the vicinity of the vehicle acquired by the vehicle exterior information detection unit 12030 or the vehicle interior information detection unit 12040.

In addition, the microcomputer 12051 can output a control command to the body system control unit 12020 based on the information outside the vehicle acquired by the vehicle exterior information detection unit 12030. For example, the microcomputer 12051 can control a head lamp in accordance with a position of a front vehicle or an oncoming vehicle detected by the vehicle exterior information detection unit 12030 and can perform cooperated control in order to achieve antiglare such as switching of a high beam to a low beam.

The audio/image output unit 12052 transmits an output signal of at least one of audio and an image to an output device capable of visually or audibly notifying an occupant of a vehicle or the outside of the vehicle of information. In the example illustrated in FIG. 18, as such an output device, an audio speaker 12061, a display unit 12062 and an instrument panel 12063 are illustrated. The display unit 12062 may include, for example, at least one of an onboard display and a head-up display.

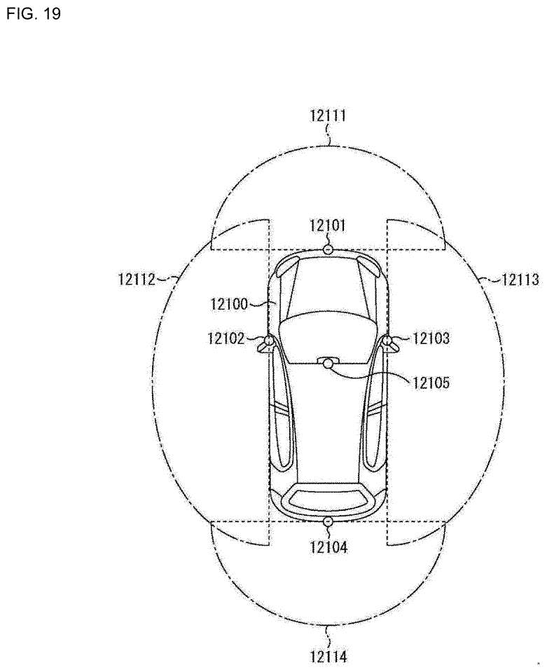

FIG. 19 is a diagram illustrating an example of positions at which the imaging unit 12031 is installed.

In FIG. 19, a vehicle 12100 includes imaging units 12101, 12102, 12103, 12104, and 12105 as the imaging unit 12031.

The imaging units 12101, 12102, 12103, 12104, and 12105 may be provided at positions such as a front nose, side-view mirrors, a rear bumper, a back door, and an upper part of a windshield in a vehicle interior of the vehicle 12100, for example. The imaging unit 12101 provided on a front nose and the imaging unit 12105 provided in an upper portion of the vehicle interior front glass mainly acquire images of a side in front of the vehicle 12100. The imaging units 12102 and 12103 provided on the side mirrors mainly acquire images of sides of the vehicle 12100. The imaging unit 12104 provided on the rear bumper or the back door mainly acquires images of a side behind the vehicle 12100. The images of a front side which are acquired by the imaging units 12101 and 12105 are mainly used for detection of preceding vehicles, pedestrians, obstacles, traffic signals, traffic signs, lanes, and the like.

FIG. 19 illustrates an example of imaging ranges of the imaging units 12101 to 12104. An imaging range 12111 is an imaging range of the imaging unit 12101 provided on the front nose, imaging ranges 12112 and 12113 are imaging ranges of the imaging units 12102 and 12103 provided in the side mirrors, and an imaging range 12114 is an imaging range of the imaging unit 12104 provided in the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each of three-dimensional objects in the imaging ranges 12111 to 12114 and temporal change in the distance(a relative speed with respect to the vehicle 12100) on the basis of distance information obtained from the imaging units 12101 to 12104. Further, the microcomputer 12051 can set an inter-vehicle distance which should be guaranteed in advance in front of a preceding vehicle and can perform automated brake control(also including following stop control) or automated acceleration control(also including following start control). In this way, it is possible to perform cooperated control in order to perform automated driving or the like in which a vehicle autonomously travels irrespective of a manipulation of a driver.

For example, the microcomputer 12051 can classify and extract three-dimensional object data regarding three-dimensional objects into two-wheeled vehicles, ordinary vehicles, large vehicles, pedestrians, and other three-dimensional objects such as utility poles on the basis of distance information obtained from the imaging units 12101 to 12104 and use the three-dimensional object data for automatic avoidance of obstacles. For example, the microcomputer 12051 identifies surrounding obstacles of the vehicle 12100 as obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than the set value and there is a possibility of collision, an alarm is output to the driver through the audio speaker 12061 and the display unit 12062, forced deceleration and avoidance steering are performed through the drive system control unit 12010, and thus it is possible to perform driving support for collision avoidance.

At least one of the imaging units 12101 to 12104 may be an infrared camera that detects infrared light. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating the outline of the object and it is determined whether the object is a pedestrian.

When the microcomputer 12051 determines that there is a pedestrian in the captured images of the imaging units 12101 to 12104, and the pedestrian is recognized, the audio/image output unit 12052 controls the display unit 12062 so that the recognized pedestrian is superimposed and displayed with a square contour line for emphasis. In addition, the audio/image output unit 12052 may control the display unit 12062 so that an icon or the like indicating a pedestrian is displayed at a desired position.

An example of the vehicle control system to which the technology according to the present disclosure (the present technology) can be applied has been described above. The technology according to the present disclosure may be applied, for example, to the imaging unit 12031 and the like among the configurations described above. Specifically, the solid-state imaging device according to the present technology can be applied to the imaging unit 12031. By applying the technology according to the present disclosure to the imaging unit 12031, it is possible to improve the performance of the imaging unit 12031.

Note that the present technology are not limited to the above-described embodiments, usage examples, and application examples, and various changes can be made without departing from the gist of the present technology.

Furthermore, the effects described in the present specification are merely exemplary and not intended to be limiting, and other effects may be provided as well.

In addition, the present technology can also adopt the following configurations.

[1] A solid-state imaging device including:

a pixel region in which a plurality of pixels are two-dimensionally disposed, wherein each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and

the number of irregularities of a concavo-convex portion included in a pixel disposed in a central portion of the pixel region and the number of irregularities of a concavo-convex portion included in a pixel disposed in a peripheral portion of the pixel region are different from each other.

[2] The solid-state imaging device according to [1],

wherein the number of irregularities of the concavo-convex portion included in the pixel disposed in the central portion of the pixel region is smaller than the number of irregularities of the concavo-convex portion included in the pixel disposed in the peripheral portion of the pixel region.

[3] The solid-state imaging device according to [1] or [2],

wherein the number of irregularities of the concavo-convex portion included in each pixel constituting the plurality of pixels changes from the pixel disposed in the central portion of the pixel region to the pixel disposed in the peripheral portion of the pixel region.

[4] The solid-state imaging device according to any one of [1] to [3],

wherein the number of irregularities of the concavo-convex portion included in each pixel constituting the plurality of pixels gradually increases from the pixel disposed in the central portion of the pixel region to the pixel disposed in the peripheral portion of the pixel region.

[5] The solid-state imaging device according to any one of [1] to [4],

wherein a pitch of a convex portion constituting the concavo-convex portion included in the pixel disposed in the central portion of the pixel region and a pitch of a convex portion constituting the concavo-convex portion included in the pixel disposed in the peripheral portion of the pixel region are different from each other.

[6] The solid-state imaging device according to any one of [1] to [5],

wherein a pitch of a convex portion constituting the concavo-convex portion included in the pixel disposed in the central portion of the pixel region is larger than a pitch of a convex portion constituting the concavo-convex portion included in the pixel disposed in the peripheral portion of the pixel region.

[7] The solid-state imaging device according to any one of [1] to [6],

wherein a pitch of a convex portion constituting the concavo-convex portion included in the pixel disposed in the central portion of the pixel region is larger than a pitch of a convex portion constituting the concavo-convex portion included in the pixel disposed in the peripheral portion of the pixel region,

the concavo-convex portion included in the pixel disposed in the central portion of the pixel region is provided in an entire inner surface of the pixel when the pixel is seen in plan view, and

the concavo-convex portion included in the pixel disposed in the peripheral portion of the pixel region is provided in an entire inner surface of the pixel when the pixel is seen in plan view.

[8] The solid-state imaging device according to any one of [1] to [7],

wherein the concavo-convex portion included in the pixel disposed in the central portion of the pixel region has a point-symmetrical shape with a center of the concavo-convex portion as a point of symmetry when seen in plan view and has a rectangular shape, and

the concavo-convex portion included in the pixel disposed in the peripheral portion of the pixel region has a point-symmetrical shape with a center of the concavo-convex portion as a point of symmetry when seen in plan view and has a rectangular shape.

[9] The solid-state imaging device according to any one of [1] to [8],

wherein the concavo-convex portion included in the pixel disposed in the central portion of the pixel region has a point-symmetrical shape with a center of the concavo-convex portion as a point of symmetry when seen in plan view and has a rectangular shape, and

the concavo-convex portion included in the pixel disposed in the peripheral portion of the pixel region has a point-symmetrical shape with a center of the concavo-convex portion as a point of symmetry when seen in plan view and has a polygonal shape.

[10] The solid-state imaging device according to any one of [1] to [9],

wherein the concavo-convex portion included in each pixel constituting the plurality of pixels is provided to cover a light converging region in which the incident light formed in the photoelectric conversion unit converges.

[11] The solid-state imaging device according to any one of [1] to [10],

wherein a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view.

[12] The solid-state imaging device according to [11],

wherein the concavo-convex portion included in the pixel disposed in the central portion of the pixel region is provided at least in a center portion in the pixel when the pixel is seen in plan view, and

the concavo-convex portion included in the pixel disposed in the peripheral portion of the pixel region is provided to extend at least from the center portion in the pixel toward a peripheral portion without reaching a boundary portion between the pixel and an adjacent pixel when the pixel is seen in plan view.

[13] The solid-state imaging device according to [11] or [12],

wherein the concavo-convex portion included in the pixel disposed in the central portion of the pixel region is provided at least in a center portion in the pixel when the pixel is seen in plan view, and

a concavo-convex portion included in a pixel disposed in a right peripheral portion in the pixel region when the pixel region is seen in plan view is provided to extend at least from the center portion in the pixel toward a left peripheral portion without reaching a boundary portion between the pixel and an adjacent pixel when the pixel is seen in plan view.

[14] The solid-state imaging device according to any one of [11] to [13],

wherein the concavo-convex portion included in the pixel disposed in the central portion of the pixel region is provided at least in a center portion in the pixel when the pixel is seen in plan view, and

a concavo-convex portion included in a pixel disposed in a left peripheral portion in the pixel region when the pixel region is seen in plan view is provided to extend at least from the center portion in the pixel toward a right peripheral portion without reaching a boundary portion between the pixel and an adjacent pixel when the pixel is seen in plan view.

[15] A solid-state imaging device including:

a pixel region in which a plurality of pixels are two-dimensionally disposed, wherein each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and

a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view.

[16] The solid-state imaging device according to [15],

wherein the concavo-convex portion included in the pixel disposed in the central portion of the pixel region is provided at least in a center portion in the pixel when the pixel is seen in plan view, and

the concavo-convex portion included in the pixel disposed in the peripheral portion of the pixel region is provided to extend at least from the center portion in the pixel toward a peripheral portion without reaching a boundary portion between the pixel and an adjacent pixel when the pixel is seen in plan view.

[17] The solid-state imaging device according to [15] or [16],

wherein the concavo-convex portion included in the pixel disposed in the central portion of the pixel region is provided at least in a center portion in the pixel when the pixel is seen in plan view, and

a concavo-convex portion included in a pixel disposed in a right peripheral portion in the pixel region when the pixel region is seen in plan view is provided to extend at least from the center portion in the pixel toward a left peripheral portion without reaching a boundary portion between the pixel and an adjacent pixel when the pixel is seen in plan view.

[18] The solid-state imaging device according to any one of [15] to [17],

wherein the concavo-convex portion included in the pixel disposed in the central portion of the pixel region is provided at least in a center portion in the pixel when the pixel is seen in plan view, and

a concavo-convex portion included in a pixel disposed in a left peripheral portion in the pixel region when the pixel region is seen in plan view is provided to extend at least from the center portion in the pixel toward a right peripheral portion without reaching a boundary portion between the pixel and an adjacent pixel when the pixel is seen in plan view.

[19] Electronic equipment on which the solid-state imaging device according to any one of [1] to [18] is mounted.

### REFERENCE NUMERALS LIST

1 (1-1, 1-2) On-chip lens

2 (2-1G, 2-2R) Color filter

4 Insulating film (flattened film)

5 (5-1, 5-2, 5-3) Light shielding film

6 (6-1, 6-2) Photoelectric conversion unit (photocliode (PD))

7 Semiconductor substrate

11 (11a-1 to 11a-4, 11b-1 to 11b-4, 11c-1 to 11c-4), 12 (12a-1 to 12a-4, 12b-1 to 12b-4, 12c-1 to 12c-4), 13 (13a-1 to 13a-4), 14 (14a-1 to 14a-4, 14b-1 to 14b-4, 14c-1 to 14c-4), 15 (15a-1 to 15a-4, 15b-1 to 15b-4, 15c-1 to 15c-4), 16 (16a-1, 16a-2, 16b-1, 16b-2), 17 (17a-1 to 17a-4, 17b-1 to 17b-4, 17c-1 to 17c-4), 18 (18a-1 to 18a-4), 19 (19a-1 to 19a-4, 19b-1 to 19b to 4, 19c-1 to 19c-4), 20 (20a-1 to 20a-4, 20b-1 to 20b-4, 20c-1 to 20c-4), 21 (21a-1 to 21a-4), 22 (22a-1 to 22a-4) Concavo-convex portion (moth-eye structure)

2e, 1001a-1 to 1001a-4, 1001b-1 to 1001b-4, 1001c-1 to 1001c-4, 1002a-1 to 1002a-4, 1002b-1 to 1002b-4, 1002c-1 to 1002c-4, 1003a-1 to 1003a-4, 1004a-1 to 1004a-4, 1004b-1 to 1004b-4, 1004c-1 to 1004c-4, 1005a-1 to 1005a-4, 1005b-1 to 1005b-4, 1005c-1 to 1005c-4, 1007a-1 to 1007a-4, 1007b-1 to 1007b-4, 1007c-1 to 1007c-4, 1008a-1 to 1008a-4, 1009a-1 to 1009a-4, 1009b-1 to 1009b-4, 1009c-1 to 1009c-4, 1010a-1 to 1010a-4, 1010b-1 to 1010b-4, 1010c-1 to 1010c-4, 1011a-1 to 1011a-4, 1012a-1 to 1012a-4 Pixel

1001a, 1001b, 1001c, 1002a, 1002b, 1002c, 1003a, 1004a, 1004b, 1004c, 1005a, 1005b, 1005c, 1007a, 1007b, 1007c, 1008a, 1009a, 1009b, 1009c, 1010a, 1010b, 1010c, 1011a, 1012a Region of four pixels of solid-state imaging device

1e, 1001, 1002, 1003, 1007, 1008, 1600 (1600a, 1600b) Solid-state imaging device

1. A solid-state imaging device comprising:
a pixel region in which a plurality of pixels are two-dimensionally disposed,
wherein each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and
the number of irregularities of a concavo-convex portion included in a pixel disposed in a central portion of the pixel region and the number of irregularities of a concavo-convex portion included in a pixel disposed in a peripheral portion of the pixel region are different from each other.

2. The solid-state imaging device according to claim 1, wherein the number of irregularities of the concavo-convex portion included in the pixel disposed in the central portion of the pixel region is smaller than the number of irregularities of the concavo-convex portion included in the pixel disposed in the peripheral portion of the pixel region.

3. The solid-state imaging device according to claim 1, wherein the number of irregularities of the concavo-convex portion included in each pixel constituting the plurality of pixels changes from the pixel disposed in the central portion of the pixel region to the pixel disposed in the peripheral portion of the pixel region.

4. The solid-state imaging device according to claim 1, wherein the number of irregularities of the concavo-convex portion included in each pixel constituting the plurality of pixels gradually increases from the pixel disposed in the central portion of the pixel region to the pixel disposed in the peripheral portion of the pixel region.

5. The solid-state imaging device according to claim 1, wherein a pitch of a convex portion constituting the concavo-convex portion included in the pixel disposed in the central portion of the pixel region and a pitch of a convex portion constituting the concavo-convex portion included in the pixel disposed in the peripheral portion of the pixel region are different from each other.

6. The solid-state imaging device according to claim 1, wherein a pitch of a convex portion constituting the concavo-convex portion included in the pixel disposed in the central portion of the pixel region is larger than a pitch of a convex portion constituting the concavo-convex portion included in the pixel disposed in the peripheral portion of the pixel region.

7. The solid-state imaging device according to claim 1,
wherein a pitch of a convex portion constituting the concavo-convex portion included in the pixel disposed in the central portion of the pixel region is larger than a pitch of a convex portion constituting the concavo-convex portion included in the pixel disposed in the peripheral portion of the pixel region,
the concavo-convex portion included in the pixel disposed in the central portion of the pixel region is provided in an entire inner surface of the pixel when the pixel is seen in plan view, and
the concavo-convex portion included in the pixel disposed in the peripheral portion of the pixel region is provided in an entire inner surface of the pixel when the pixel is seen in plan view.

8. The solid-state imaging device according to claim 1,
wherein the concavo-convex portion included in the pixel disposed in the central portion of the pixel region has a point-symmetrical shape with a center of the concavo-convex portion as a point of symmetry when seen in plan view and has a rectangular shape, and
the concavo-convex portion included in the pixel disposed in the peripheral portion of the pixel region has a point-symmetrical shape with a center of the concavo-convex portion as a point of symmetry when seen in plan view and has a rectangular shape.

9. The solid-state imaging device according to claim 1,
wherein the concavo-convex portion included in the pixel disposed in the central portion of the pixel region has a point-symmetrical shape with a center of the concavo-convex portion as a point of symmetry when seen in plan view and has a rectangular shape, and
the concavo-convex portion included in the pixel disposed in the peripheral portion of the pixel region has a point-symmetrical shape with a center of the concavo-convex portion as a point of symmetry when seen in plan view and has a polygonal shape.

10. The solid-state imaging device according to claim 1, wherein the concavo-convex portion included in each pixel constituting the plurality of pixels is provided to cover a light converging region in which the incident light formed in the photoelectric conversion unit converges.

11. The solid-state imaging device according to claim 1, wherein a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view.

12. The solid-state imaging device according to claim 11,
wherein the concavo-convex portion included in the pixel disposed in the central portion of the pixel region is provided at least in a center portion in the pixel when the pixel is seen in plan view, and
the concavo-convex portion included in the pixel disposed in the peripheral portion of the pixel region is provided to extend at least from the center portion in the pixel toward a peripheral portion without reaching a boundary portion between the pixel and an adjacent pixel when the pixel is seen in plan view.

13. The solid-state imaging device according to claim 11,
wherein the concavo-convex portion included in the pixel disposed in the central portion of the pixel region is provided at least in a center portion in the pixel when the pixel is seen in plan view, and
a concavo-convex portion included in a pixel disposed in a right peripheral portion in the pixel region when the pixel region is seen in plan view is provided to extend at least from the center portion in the pixel toward a left peripheral portion without reaching a boundary portion between the pixel and an adjacent pixel when the pixel is seen in plan view.

14. The solid-state imaging device according to claim 11,
wherein the concavo-convex portion included in the pixel disposed in the central portion of the pixel region is provided at least in a center portion in the pixel when the pixel is seen in plan view, and
a concavo-convex portion included in a pixel disposed in a left peripheral portion in the pixel region when the pixel region is seen in plan view is provided to extend at least from the center portion in the pixel toward a right peripheral portion without reaching a boundary portion between the pixel and an adjacent pixel when the pixel is seen in plan view.

15. A solid-state imaging device comprising:
a pixel region in which a plurality of pixels are two-dimensionally disposed,
wherein each of the pixels includes a photoelectric conversion unit and a concavo-convex portion, the photoelectric conversion unit photoelectrically converting incident light formed on a semiconductor substrate, and the concavo-convex portion being positioned above the photoelectric conversion unit and formed on a light receiving surface side of the semiconductor substrate, and
a position at which the concavo-convex portion included in the pixel disposed in the central portion of the pixel region is provided in the pixel when the pixel is seen in plan view is different from a position at which the concavo-convex portion included in the pixel disposed in the peripheral portion of the pixel region is provided in the pixel when the pixel is seen in plan view.

16. The solid-state imaging device according to claim 15,
wherein the concavo-convex portion included in the pixel disposed in the central portion of the pixel region is provided at least in a center portion in the pixel when the pixel is seen in plan view, and
the concavo-convex portion included in the pixel disposed in the peripheral portion of the pixel region is provided to extend at least from the center portion in the pixel toward a peripheral portion without reaching a boundary portion between the pixel and an adjacent pixel when the pixel is seen in plan view.

17. The solid-state imaging device according to claim 15,
wherein the concavo-convex portion included in the pixel disposed in the central portion of the pixel region is provided at least in a center portion in the pixel when the pixel is seen in plan view, and
a concavo-convex portion included in a pixel disposed in a right peripheral portion in the pixel region when the pixel region is seen in plan view is provided to extend at least from the center portion in the pixel toward a left peripheral portion without reaching a boundary portion between the pixel and an adjacent pixel when the pixel is seen in plan view.

18. The solid-state imaging device according to claim 15,
wherein the concavo-convex portion included in the pixel disposed in the central portion of the pixel region is provided at least in a center portion in the pixel when the pixel is seen in plan view, and
a concavo-convex portion included in a pixel disposed in a left peripheral portion in the pixel region when the pixel region is seen in plan view is provided to extend at least from the center portion in the pixel toward a right peripheral portion without reaching a boundary portion between the pixel and an adjacent pixel when the pixel is seen in plan view.

19. Electronic equipment on which the solid-state imaging device according to claim 1 is mounted.

20. Electronic equipment on which the solid-state imaging device according to claim 15 is mounted.
